(19) United States
(12) Patent Application Publication
(10) Pub. No.: US 2026/0246238 A1
(43) Pub. Date: Aug. 20, 2026

(54) FLIP-AND-TRANSFER RIDGE LASER DIODE STRUCTURE AND METHOD

(71) Applicant: Kyocera Corporation, Kyoto (JP)

(72) Inventors: Changmin Lee, Santa Barbara, CA (US); Christian Zollner, Santa Barbara, CA (US); Kentaro Murakawa, Santa Barbara, CA (US); Nick Pfister, Santa Barbara, CA (US); James W. Raring, Santa Barbara, CA (US); Meng Zhang, San Jose, CA (US); Donghong Li, Fremont, CA (US)

(73) Assignee: Kyocera Corporation, Kyoto (JP)

(21) Appl. No.: 19/537,965

(22) Filed: Feb. 12, 2026

Related U.S. Application Data
(60) Provisional application No. 63/758,833, filed on Feb. 14, 2025.

(51) Int. Cl. H01S 5/22; H01S 5/34

(52) U.S. Cl. CPC H01S 5/2202; H01S 5/34

(57) ABSTRACT

Improved sidewall passivation and device structures for semiconductor devices are disclosed. The sidewall passivation may include a protection ridge with a sidewall shelf. Some embodiments may use trenches to define lateral dimensions of device regions. The device may start on a donor substrate, and after formation of the sidewall shelves, the mesa may be transferred onto a carrier substrate for finishing. The device may include cavity trenches, as necessary, and after flipping and transfer to the carrier substrate, may include shallow trenches filled with conductive material to facilitate heat dissipation.

### CROSS-REFERENCES TO RELATED APPLICATIONS

The present application claims priority to U.S. Provisional Application No. 63/758,833, filed Feb. 14, 2025, the contents of which are incorporated herein by reference in their entirety for all purposes.

### BACKGROUND

Devices fabricated from III-V semiconductor materials, such as gallium arsenide (GaAs) and gallium nitride (GaN), are foundational to modern electronics, playing a critical role in light-emitting devices such as light emitting diodes (LEDs) and laser diodes. Achieving high-performance devices requires epitaxial structures with minimal defect densities and superior crystal quality, which is optimally realized by growing device layers on native substrates. Native substrates facilitate the formation of pseudomorphic epitaxial layers with reduced strain-related defects. However, the synthesis of single-crystal GaN substrates is an extraordinarily challenging task. Traditional methods, such as the Czochralski process, are not feasible for GaN due to the extreme process conditions required. Alternative approaches have been investigated, but scaling GaN substrates to larger wafer sizes remains a significant challenge. These ongoing challenges underscore the need for continued innovation in materials, device structures, and fabrication processes to improve the performance and reduce the costs of laser diodes.

### SUMMARY

Embodiments described herein provide improved structures and fabrication methods for ridge-type laser diodes. Some embodiments incorporate a novel sidewall passivation scheme utilizing ridges or shelves to enhance the resilience of the active region during manufacturing and subsequent handling. Some embodiments detail processes beginning with the formation of epitaxial layers on donor substrates (e.g., GaN or GaAs), followed by creation of ridge and trench structures, deposition of passivation and insulating layers, and use of a flip-and-transfer technique to mount mesa structures onto carrier substrates for final device processing. Some embodiments also use trenches to define lateral dimensions of light cavity ridge structures and may integrate post-transfer trenches filled with thermally conductive materials for effective heat dissipation. These advancements address longstanding challenges in laser diode fabrication by improving device reliability, manufacturability, reducing cost, and enhancing thermal management across a variety of substrate materials and emission wavelengths.

As an example, in accordance with an embodiment, a method of forming a mesa structure providing active region protection, where the mesa structure includes a plurality of epitaxially-grown semiconductor layers configured to enable generation of photonic emissions within a cavity, and the mesa structure is characterized by a length with two ends, includes forming an epitaxially-grown sacrificial layer overlying a top surface of a donor substrate; forming an epitaxially-grown first cladding region overlying the sacrificial layer; forming an epitaxially-grown quantum well region overlying the first cladding region; forming an epitaxially-grown second cladding region overlying the quantum well region, the second cladding region having a substantially flat top surface; etching the sacrificial layer, the first cladding region, the quantum well region, and the second cladding region to form sidewalls extending from the top surface of the second cladding region to the donor substrate to form an overall mesa shape when viewed in cross section perpendicular to the length, the sidewalls including ridge cutouts so as to form a sub-mesa within the mesa shape, the ridge cutouts extending from the top surface of the second cladding region a distance down each sidewall toward the donor substrate and terminating within the first cladding region to form shelves; forming a first passivation material over the top surface of the second cladding region and the sidewalls and the shelves of the ridge cutouts; forming a via extending through the first passivation material to the top surface of the second cladding region; forming a contact region in the via, the contact region formed on or within an upper portion of the second cladding region; and forming an anchor material on a surface of the mesa structure, wherein along the length of the mesa structure, the anchor material extends down the sidewalls of the mesa structure and terminates at the top surface of the donor substrate to form anchor portions, and wherein along the ends of the mesa structure, the anchor material extends down the sidewalls of the mesa structure and terminates above the top surface of the donor substrate to form non-anchor portions.

In an embodiment, the first passivation layer covers the quantum well region along the sidewalls of the ridge cutouts, the method further comprising etching at least one of the sacrificial layer or the donor substrate exposed along the ends of the mesa structure. In some embodiments, the etching may remove a portion of the donor substrate. In other embodiments, the etching may remove the donor substrate to expose a portion of the first cladding region. Some embodiments may also include forming a mask on a portion of the first cladding region exposed in the etching; and etching the first cladding region to remove portions of the first cladding region exposed by the mask, wherein the etching does not remove all of the passivation material on the sidewalls of the ridge cutouts.

In another embodiment, the method also includes forming a bonding material on the top surface of the second cladding region; bonding the mesa structure to a carrier substrate; removing the sacrificial layer so that the mesa structure is coupled to the donor substrate by the anchor portions; and removing the donor substrate from the mesa structure by detaching the anchor portions.

In accordance with another embodiment, a mesa structure provides active region protection, includes a plurality of semiconductor layers, and is characterized by a length with two ends. The mesa structure includes a donor substrate having a top surface; a sacrificial layer overlying the top surface of the donor substrate; a first semiconductor region overlying the sacrificial layer; an active region overlying the first semiconductor region; a second semiconductor region overlying the active region, the second semiconductor region having a substantially flat top surface; sidewalls extending from the top surface of the second semiconductor region to the donor substrate to provide an overall mesa shape when viewed in cross section perpendicular to the length, the sidewalls including ridge cutouts so as to form a sub-mesa within the mesa shape, the ridge cutouts extending from the top surface of the second semiconductor region a distance down each sidewall toward the donor substrate and terminating within the first semiconductor region to form shelves; a first passivation material coating the top surface of the second semiconductor region and the sidewalls and the shelves of the ridge cutouts; a contact region on or within an upper portion of the second semiconductor region; a via extending through the first passivation material to the contact region; and an anchor material coating a surface of the mesa structure, wherein along the length of the mesa structure, the anchor material extends down the sidewalls of the mesa structure and terminates at the top surface of the donor substrate to form anchor portions, and wherein along the ends of the mesa structure, the anchor material extends down the sidewalls of the mesa structure and terminates above the top surface of the donor substrate to form non-anchor portions.

In an embodiment, the mesa structure also includes a pair of trenches each extending from the top surface of the second semiconductor region toward the active region, the pair of trenches separated from each other by a lateral distance. The pair of trenches may extend into the second semiconductor region and terminate before reaching the active region, the pair of trenches may extend into the second semiconductor region and terminate within the active region, or the pair of trenches extend through the second semiconductor region and the active region. In some embodiments, a bottom corner of at least one of the pair of trenches has a curved shape, or at least one of the pair of trenches has, in cross section, two corners on a bottom side, and one of the corners has a greater curvature than the other corner. The first passivation material may line sides of at least one of the pair of trenches, and/or a thickness of the first passivation material along the bottom is greater than a thickness of the first passivation material along the sides. The first passivation material may line sides and a bottom of at least one of the pair of trenches to form a cavity in a center portion of the trench, or the first passivation material may fill at least one of the pair of trenches.

In another embodiment, a thickness between the top surface of the donor substrate and the top surface of the second semiconductor region is 20 μm or less.

In another embodiment, a thickness of the first passivation layer is greater on the top surface of the second semiconductor region than on the sidewalls of the ridge cutouts.

In another embodiment, the second semiconductor region comprises a p-type semiconductor region.

In another embodiment, the first passivation material comprises a first film of aluminum nitride or aluminum oxynitride and a second film of oxide overlying the first film.

In another embodiment, the donor substrate contains at least gallium and nitrogen.

In another embodiment, the donor substrate contains at least gallium and arsenic.

In yet another embodiment, the first semiconductor region includes a first cladding region, the active region includes a quantum well region, and the second semiconductor region includes a second cladding region.

In accordance with yet another embodiment, a mesa structure on a carrier substrate includes a plurality of semiconductor layers and comprises a bonding material coupling the mesa structure to the carrier substrate, wherein the bonding material is coupled to a contact region of the mesa structure; a first semiconductor region comprising the contact region; an active region overlying the first semiconductor region; and a second semiconductor region overlying the active region, the second semiconductor region and the first semiconductor region having substantially flat surfaces that are substantially parallel to each other and form opposing upper and lower boundaries of the mesa structure respectively, the substantially flat surface of the first semiconductor region coupled to the carrier substrate by the bonding material; wherein the first semiconductor region, the active region, and a portion of the second semiconductor region form a first mesa shape, and the remaining portion of the second semiconductor region forms a second mesa shape, wherein sidewalls of the first mesa shape extend upward and outward from the substantially flat surface of the first semiconductor region in a direction toward the second mesa shape, and a passivation material extends along the sidewalls of the first mesa shape, and wherein sidewalls of the second mesa shape extend downward and outward from the substantially flat surface of the second semiconductor region in a direction toward the first mesa shape.

In an embodiment, the first semiconductor region includes a p-type cladding region, the active region includes a quantum well region, and the second semiconductor region includes an n-type cladding region.

### BRIEF DESCRIPTION OF THE DRAWINGS

The accompanying drawings are included to provide further understanding of the described embodiments. Figures illustrate various structures and process steps referenced in the detailed description. No attempt is made to show structural details beyond what is necessary for a fundamental understanding of the invention.

FIG. 1 is a simplified cross-sectional view of an exemplary mesa structure in accordance with some embodiments.

FIG. 2 is a simplified cross-sectional view of an exemplary mesa structure with improved sidewall passivation in accordance with some embodiments.

FIG. 3 is a simplified cross-sectional view of the exemplary mesa structure of FIG. 2 after flipping and bonding to a carrier substrate in accordance with some embodiments.

FIGS. 4-6 provide simplified cross-sectional views of exemplary mesa structures where cavity width is defined by edges of the mesa structure in accordance with some embodiments.

FIGS. 7a-7c provide simplified cross-sectional views of various features that may be included in mesa structures in accordance with some embodiments.

FIGS. 8a-8c, 9a-9b, and 10a-10b provide simplified cross-sectional views of various features that may be included in mesa structures in accordance with some embodiments.

FIGS. 11-25 are simplified cross-sectional views illustrating exemplary processes for forming mesa structures on donor substrates and transferring the mesa structures to carrier substrates in accordance with some embodiments.

FIGS. 26a-26f provide simplified cross-sectional views illustrating an exemplary process flow and device structure in accordance with some embodiments.

FIGS. 27a-27f provide simplified cross-sectional views illustrating exemplary processes for forming anchor structures in accordance with some embodiments.

FIGS. 28a-28b and 29a-29b provide simplified cross-sectional views illustrating exemplary device structures in accordance with some embodiments.

FIGS. 30a-30f provide simplified cross-sectional views illustrating exemplary flip and transfer processes utilizing anchor schemes in accordance with some embodiments.

FIGS. 31a-31b provide simplified cross-sectional views illustrating an exemplary flip and transfer process in accordance with some embodiments.

FIGS. 32a-32b and 33a-33c provide simplified cross-sectional views illustrating exemplary structures with n-side trenches in accordance with some embodiments.

### DETAILED DESCRIPTION

This disclosure, without limitation, relates to structures and methods for forming improved sidewall passivation to provide protective coatings on ridge-type laser diodes, including variants with gallium and nitrogen, gallium and arsenic, indium, aluminum, and phosphorous containing materials.

A ridge-type laser diode is typically formed using a substrate (donor substrate) on which thin films producing desired light emission can be fabricated. For blue, green, or violet emission, the donor substrate may include a gallium and nitrogen-containing material (e.g., GaN). For red, infrared, yellow, or amber emission, the donor substrate may include a gallium and arsenic-containing material (e.g., GaAs). The donor substrate supports formation of thin-film crystalline layers selected for forming a diode where electron-hole recombination and photonic emission occur. Sapphire, silicon or other materials may be used if suitable for epitaxial film growth. For a GaN-based laser diode, the thin films may be variations and combinations of gallium, nitrogen, indium, aluminum, phosphorous, or other doping materials. For a GaAs-based laser diode, the thin films may be variations and combinations of gallium, arsenic, indium, aluminum, phosphorous or other doping materials. Designs often employ a quantum well structure comprising several thin film layers of various compositions. Coherent photonic emission is enabled by light-reflecting surfaces, typically reflective coatings on facets at either end of the ridge structure, designed to enable light to exit from one end.

In some embodiments, exemplary processes include providing a donor substrate and forming a sacrificial region, forming cladding layers and an active multi-quantum well (MQW) region, patterning and etching ridge structures (e.g., using photolithography and etching), depositing bonding material to facilitate flip-and-transfer to a carrier substrate (e.g., silicon carbide, silicon, diamond, aluminum nitrode, copper), and completing device processing with electrical contacts, insulation, and electrical wiring.

The resultant laser diode may be Fabry-Perot style, emitting light at a wavelength within a target range (e.g., blue/violet/green: 380 nm to 565 nm; red/yellow/amber: 565 nm to 750 nm; infrared: 750 nm to 1mm). The laser diode may be multi-mode or single-mode. The laser diode may be further enhanced with a structure to increase the light source power output such as distributed feedback (DFB).

An exemplary transfer process for fabricating such a ridge laser diode and examples of types of resultant structures are generally described in the following patents and patent applications, the contents of which are incorporated herein by reference for all purposes:
“Manufacturable Laser Diode Formed on C-Plane Gallium and Nitrogen Material”, U.S. Pat. No. 11,569,637, filed Jan. 7, 2021;
“Manufacturable Laser Diode”, U.S. Pat. No. 9,379,525, filed Jun. 23, 2014;
“Manufacturable Thin Film Gallium and Nitrogen Containing Devices Integrated with Silicon and Electronic Devices”, U.S. Pat. No. 10,854,776, filed Feb. 20, 2020;
“Multi-Emitter Laser Device Structures”, U.S. patent application Ser. No. 18/754,914, filed Jun. 26, 2024; and
“Manufacturable Gallium and Nitrogen Containing Single Frequency Laser Diode”, U.S. Pat. No. 12,464,802, filed Jun. 27, 2022.

Additional examples of types of laser diodes are generally described in the following patents, the contents of which are incorporated herein by reference for all purposes:
“Optical Device Structure Using GaN substrates and Growth Structures for Laser Applications”, U.S. Pat. No. 11,862,937, filed Nov. 10, 2020; and
“Narrow Sized Laser Diode”, U.S. Pat. No. 9,088,135, filed Jun. 27, 2013.

Drawings are provided to facilitate the description of exemplary structures and process steps. All drawings are simplified and dimensions are for example purposes only. The drawings are not drawn to scale. Some features that can be implemented by a person skilled in the art may be omitted. Drawings show an example of a single laser diode that may be one of several formed on a substrate. Views are cross-sectional.

There is disclosed an improved sidewall passivation scheme to make the partially-completed mesa structure more resilient to etching steps that may otherwise penetrate the sidewalls on either side of the active portion of the laser diode and etch the delicate quantum well structure. The sidewall of the mesa structure may be parallel to a thickness direction or inclined with respect to the thickness direction.

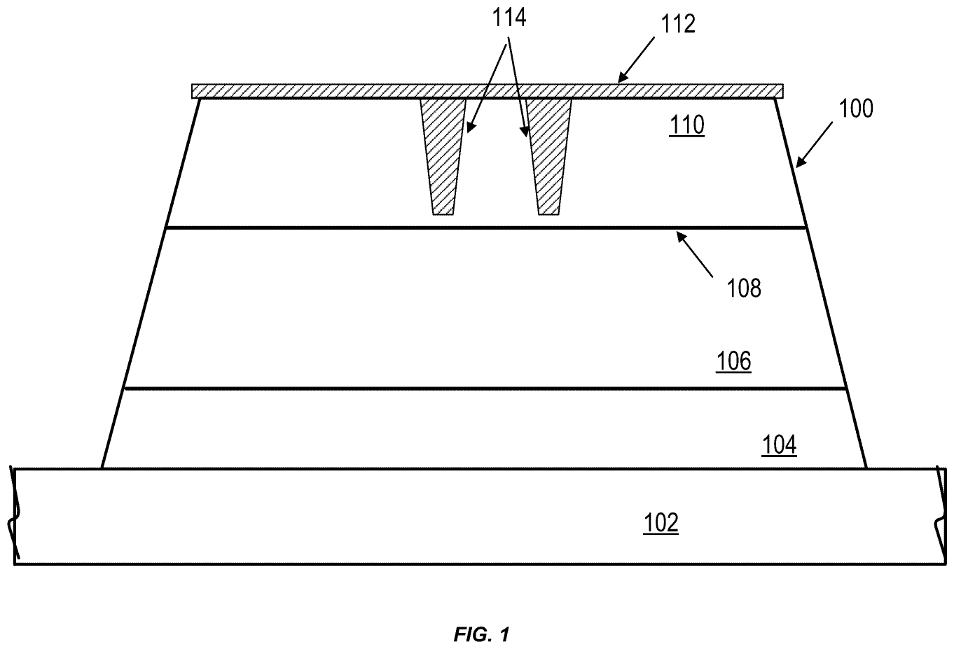

FIG. 1 shows a side-view of an exemplary mesa structure 100, which may be labelled as a “donor,” for a low-power/single mode laser diode design. Starting with the bottom portion, there is a donor substrate 102. On top of the donor substrate 102 is a sacrificial layer (SAC) 104 that is fabricated so that it can be removed later. Although this embodiment describes an example in which the donor substrate 102 is removed by etching the SAC 104, the present disclosure is not limited thereto. For example, in a case where the SAC 104 is not provided, and the first cladding region 106 is located directly on the donor substrate 102, the donor substrate 102 can be removed by polishing from the side opposite to the first cladding region 106 of the donor substrate 102. In this case, the entire donor substrate 102 or only a portion of the donor substrate 102 may be removed by polishing. The polishing can be performed using, for example, chemical mechanical polishing.

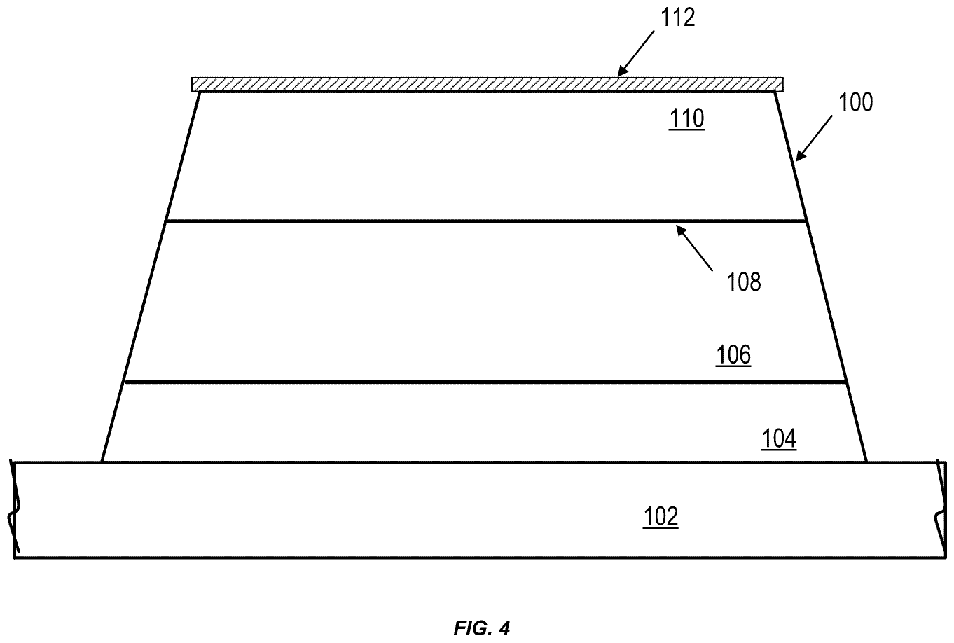

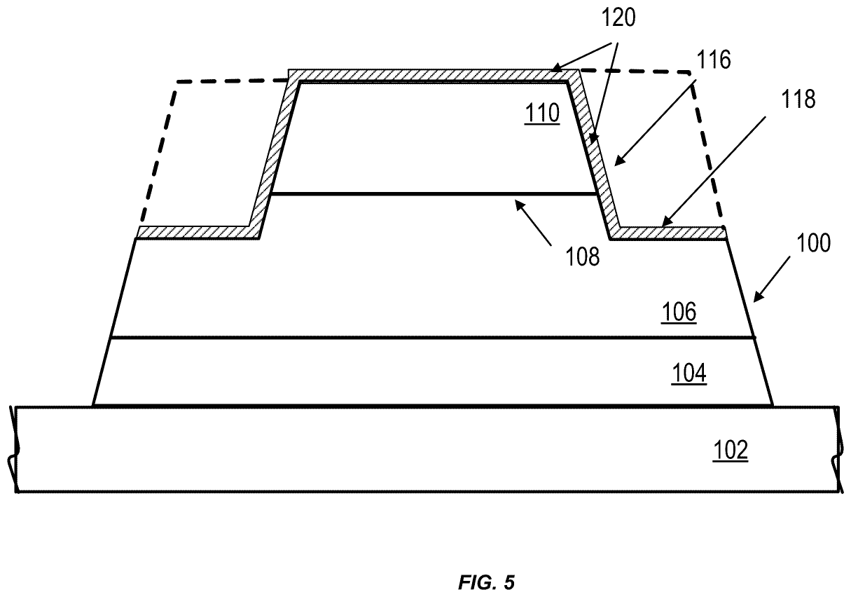

Continuing with the example of FIG. 1, overlying the SAC 104 is a first cladding region 106 (typically comprising an n-type material), above the first cladding region 106 is a multi-quantum well (MQW) region 108 that may include multiple layers of 1-6 semiconductor films, selected to produce a junction and active region effective to generate desired light emission. The MQW region 108 is followed by a protective region that may include a second cladding region 110 (typically comprising a p-type material). In some configurations, the MQW region 108 may be within the first cladding region 106. In the example of FIG. 1 and other figures, there may be trench structures 114, typically two trenches, extending from a top surface of the second cladding region 110 to define a width of and contain a cavity region (not shown) wherein most of the electron-hole recombination and photon release occurs. Note that some multi-mode laser diodes may not include the trenches 114, with the cavity width defined by edges of the mesa structure 100. FIGS. 4-6 provide examples where the cavity width is defined by the edges of the mesa structure 100. On top of the mesa 100 may be an insulation film 112, which in the example of FIG. 1 is shown to deposit into the trenches 114 as well as on top of the mesa 100. Not shown is the additional structure which may be contact points on which a bonding material is deposited so that, when the mesa structure 100 is patterned using a patterning process such as photolithography and etch, and subsequently removed from the donor substrate 102 by etching the SAC 104, the mesa structure 100 can be flipped over and positioned on a predetermined location on a carrier substrate to form a laser diode structure mounted on the carrier substrate. The carrier substrate may also be called a submount substrate.

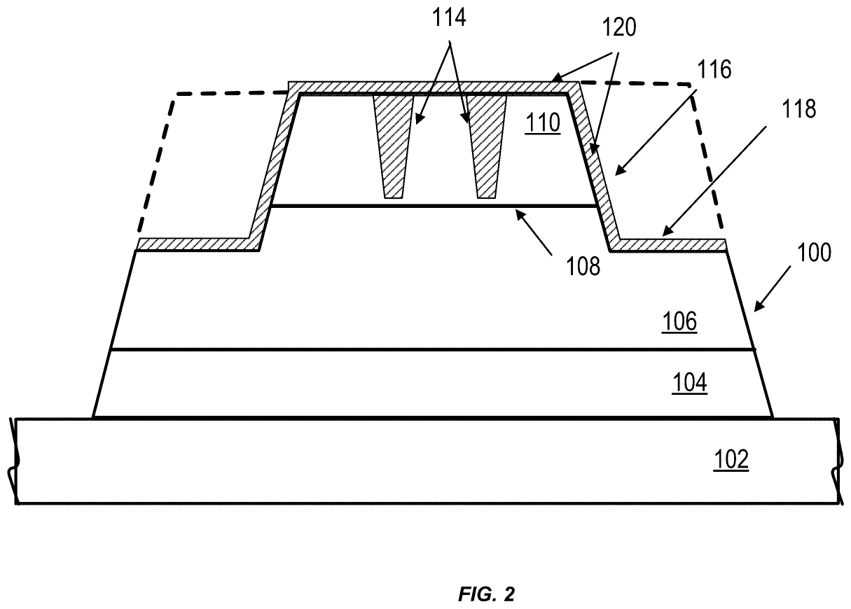

FIG. 2 shows an exemplary structure of the improved sidewall passivation 120 with a protection ridge 116. The insulation film 112 shown in FIG. 1 may be used during patterning and etching to form the protection ridge 116 structure. The sidewall passivation 120 may include some of the insulation film 112 along the top of the mesa structure 100. The cross-sectional view is of the same type of low power/single mode laser diode as depicted in FIG. 1. There is the donor substrate 102, with the SAC 104 thereon, followed by a first cladding 106, a MQW region 108, and a second cladding 110. There may be trenches 114 extending through the second cladding and optionally into or through the MQW region 108 to define and contain the light emitting cavity portion.

The protection ridge 116 structure, which may be described as a “shelf” 118 emanating out of the edge of the mesa 100, may be formed before or after the trenches 114 are formed, but preferably the protection ridges 116 are formed after the trenches 114 are formed. The trenches 114 may be filled with insulating material before or after the protection ridge 116 structures are formed. The trenches 114 may each have different shapes. The trenches 114 may also each have different depths. The trench 114 may have a rectangular cross section, or may have a shape whose width decreases in a depth direction. After forming the “shelves” 118 and trenches 114, a passivation material 120 is formed on the entire surface of the wafer. This passivation material 120 protects the MQW 108 material which is exposed by the protection ridge 116 and shelf 118 structure. As shown in FIG. 2, the shelves 118 may be a plane that is perpendicular to the thickness direction, or may be a plane that is inclined upward or downward in the thickness direction. When the shelves 118 are inclined downward, an angle formed by the shelves 118 with respect to a plane perpendicular to the thickness direction may be set to be different from an angle formed by the sidewalls of the mesa structure with respect to the plane perpendicular to the thickness direction. For example, the angle formed by the shelves 118 may be set to be smaller than the angle formed by the sidewalls of the mesa structure.

After the passivation material 120 has been formed, an etch step is used to form the final mesa structure 100 before flipping and transfer, which defines the mesa width at the first cladding 106 and SAC 104. The etch may be a plasma etch. A two-step etch may be used to etch the passivation material 102 and the epitaxial materials, respectively. The insulation passivation material 120 covering the protection ridges 116 is sufficiently thick and of a material that will serve to protect the protection ridge 116 sidewall from a subsequent etch process that is used to remove the SAC 104 so that the mesa 100 can be removed from the donor substrate 102. The insulation material 120 covering the protection ridges 116 may be the same material as the insulation material filling the trenches 114, or it may be different insulation material.

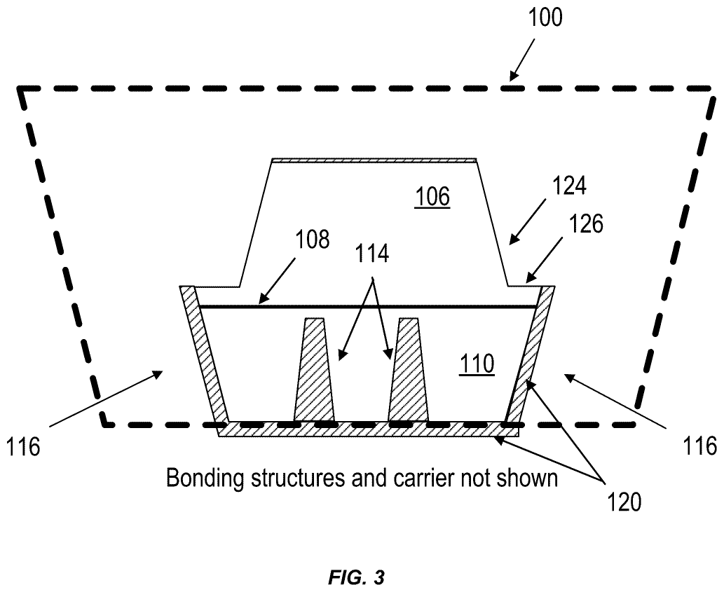

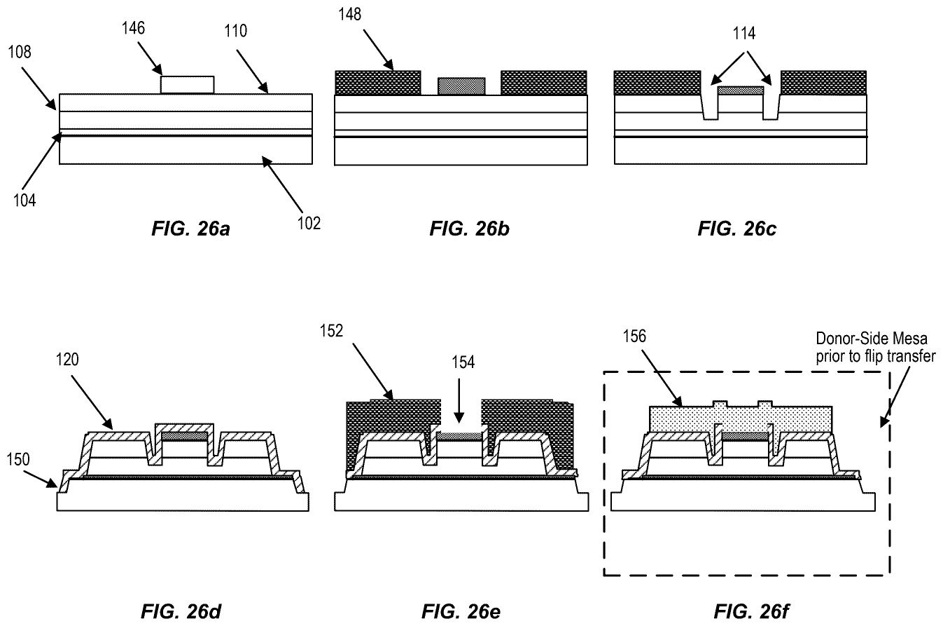

FIG. 3 shows a mesa 124 with the protection ridge 116 structure of FIG. 2, after flipping and bonding to a carrier substrate. The carrier substrate is not shown, and the bonding regions which are now on the bottom side of the mesa 124 are also not shown (see FIGS. 26a-26f, 27a-27f, 28a-28b, 29a-29b, and 30a-30f for examples of bonding regions). The insulation material 120 on the sidewall of the protection ridge 116 preferably remains, but in some embodiments it may be removed. Also included in FIG. 3 is an outline (dashed line) showing the original dimensions of the mesa 100 for illustrative purposes only. The protection ridge 116 sidewall portions remain. The protection ridge shelf 118 is removed as part of a mesa-shrinking etch that both laterally narrows and vertically shortens the mesa 124. The extent of the mesa-shrinking etch is determined by laser diode design factors including the appropriate height and width suitable for waveguide requirements, desired heat dissipation effects, and if the laser diode will be part of a multi-emitter bar, then the desired distance between the multiple emitters and ability to isolate. For purposes of the laser diode design considerations, the mesa-shrinking etch may include a lateral narrowing of the n-side (on the top side post-flip) which may further result in a new n-side shelf 126 based on dimensional requirements of the laser diode design to meet the performance criteria. The top surface of the now-flipped device may be etched back to modify the device height, and contact points are created for subsequent wiring to impart electrical voltage to the device.

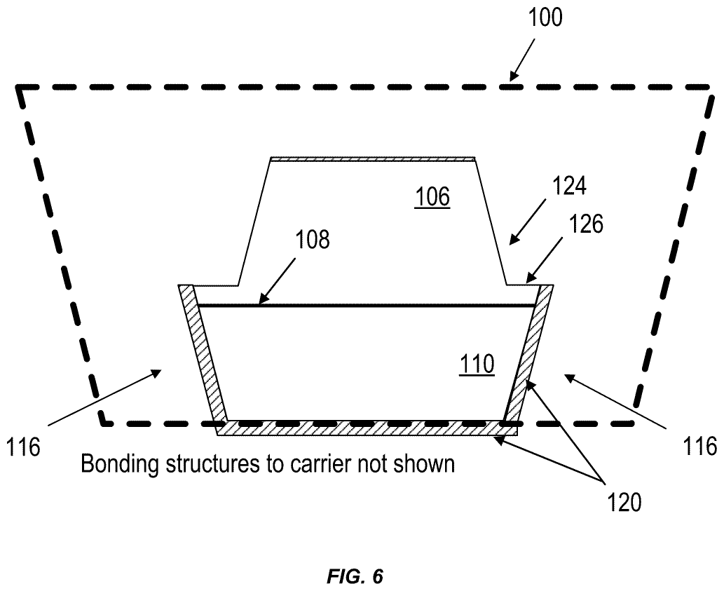

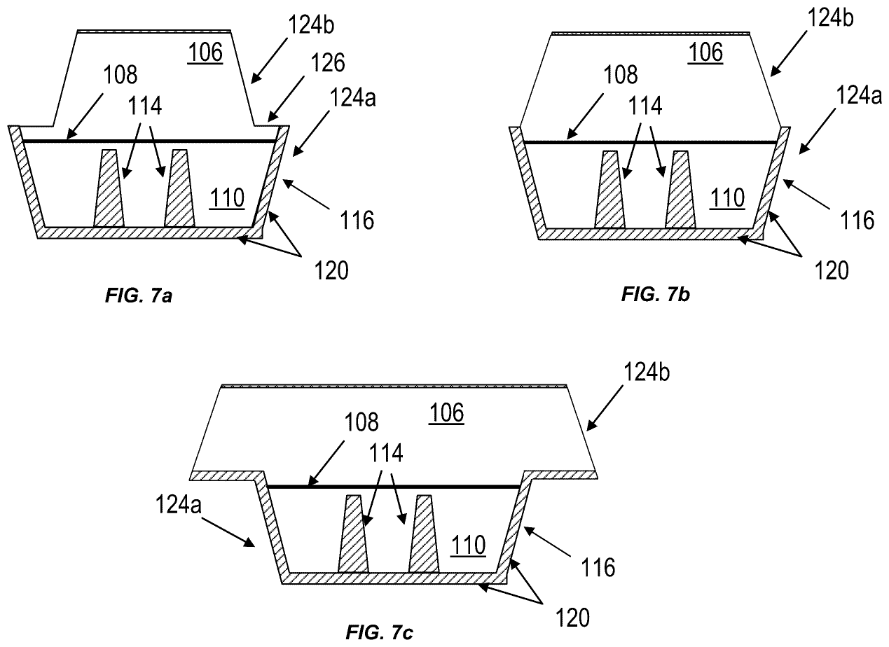

FIGS. 7a-7c, 8a-8c, 9a-9b, and 10a-10b provide simplified cross-sectional views of various features that may be included in mesa structures in accordance with some embodiments. In FIG. 7a, the mesa structure is similar to that of FIG. 6. In this example, the structure is identified as having a first mesa shape 124a and a second mesa shape 124b. In embodiments that include trenches 114, the first mesa shape 124a includes the trenches 114. The first mesa shape 124a also includes the MQW region 108 and the second cladding region 110 (the second cladding region 110 may comprise a p-type material). The second mesa shape 124b includes the first cladding 106 (the first cladding region 106 may comprise an n-type material). Based on the orientation of the first mesa shape 124a and second mesa shape 124b in FIGS. 7a-7c, a bottom (or surface that is bonded to a carrier substrate) of the first mesa shape 124a is substantially flat and a top of the second mesa shape 124b is also substantially flat.

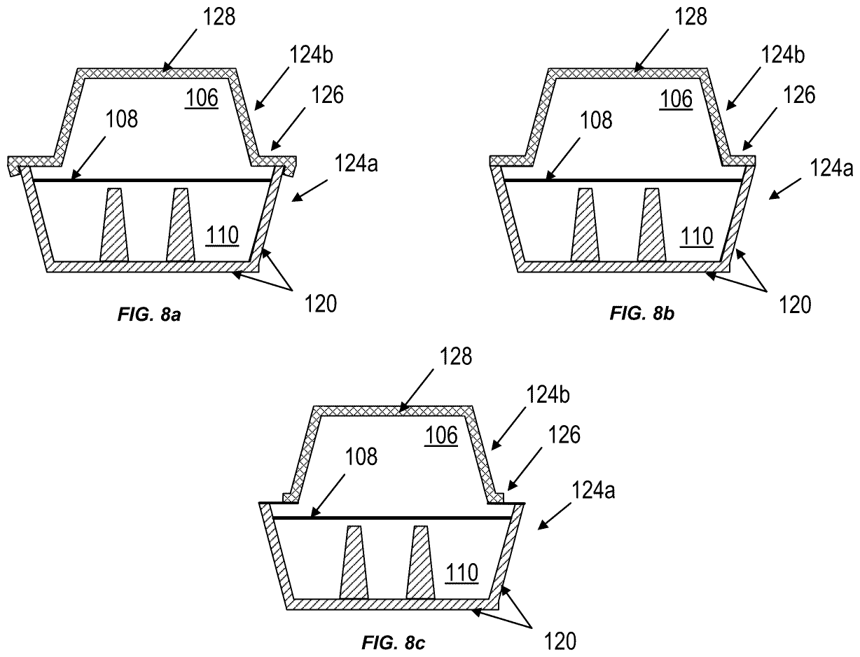

Like FIG. 6, the carrier substrate and bonding regions are not shown in FIGS. 7a-7c (or FIGS. 8a-8c, 9a-9b, and 10a-10b). In some embodiments, the first cladding region 106, the MQW region 108, and the second cladding region 110 as shown in FIGS. 7a-7c may have a combined thickness in a vertical direction of about 20 μm or less. The widths of both the first mesa shape 124a and the second mesa shape 124b become narrower as vertical distance from the shelf 126 increases.

Also, in some embodiments, a sidewall angle of the first mesa shape 124a may be greater than a sidewall angle of the second mesa shape 124b. In other embodiments, the sidewall angle of the first mesa shape 124a may be smaller than the sidewall angle of the second mesa shape 124b.

Further, in some embodiments, a height of the first mesa shape 124a (measured from the shelf 126) may be greater than a height of the second mesa shape 124b (also measured from the shelf 126). In other embodiments, the height of the first mesa shape 124a may be less than the height of the second mesa shape 124b.

In the examples of FIGS. 7a-7c, FIG. 7b shows an embodiment where a width of the second mesa shape 124b is about the same as a width of the first mesa shape 124a. In contrast, FIG. 7a shows an embodiment where the width of the second mesa shape 124b is less than the width of the first mesa shape 124a, and FIG. 7c shows an embodiment where the width of the second mesa shape 124b is greater than the width of the first mesa shape 124a.

The examples of FIGS. 8a-8c each include a second passivation film 128 covering the second mesa 124b. In FIG. 8a, the second passivation film 128 overlaps passivation material 120 covering the first mesa 124a. In FIG. 8b, the second passivation film 128 abuts the passivation material 120, and in FIG. 8c, there is a gap between the second passivation film 128 and the passivation material 120. In some embodiments, a thickness of the passivation material 120 may be greater (or thicker) than a thickness of the second passivation film 128. The second passivation film 128 may be made of the same material as the passivation material 120 or of a different material. Since the passivation material 120 is in contact with the MQW 108, a material having a higher thermal conductivity than that of the second passivation film 128 may be used for the passivation material 120.

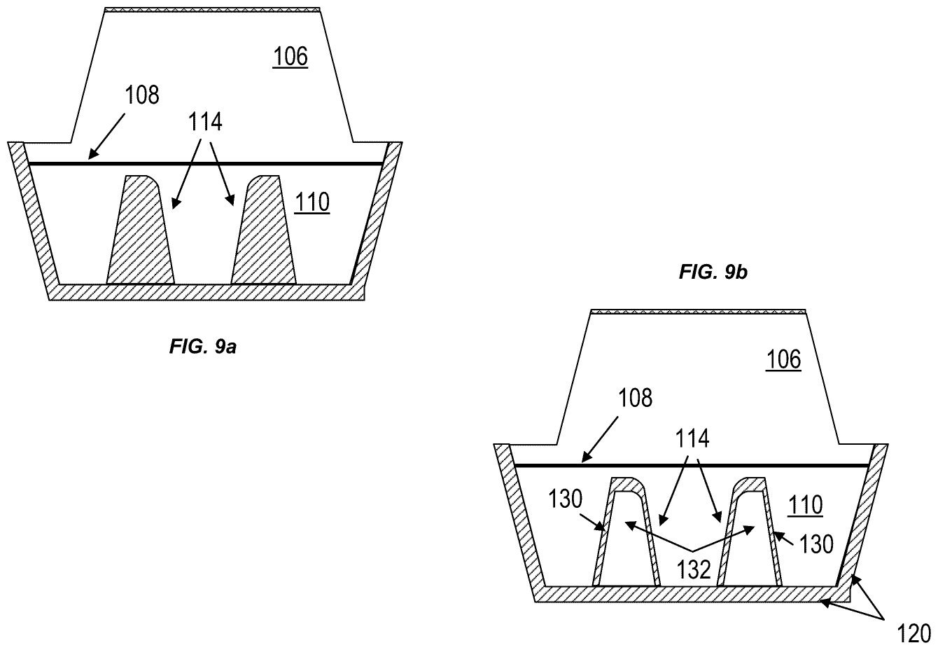

In the examples of FIGS. 9a-9b, one bottom corner of the trenches 114 is curved more than the other bottom corner of the trenches 114. In some embodiments, both of the bottom corners of each of the trenches 114 may be curved. As shown in FIG. 9a-9b, the two trenches 118 may have their opposing bottom corners curved. Further, in other embodiments, only one bottom corner of one of the adjacent trenches 114 may be curved. In FIG. 9b, in addition to having one bottom corner of the trenches 114 being curved more than the other bottom corner, this example also includes a third passivation layer 130 lining sides and a bottom of the trenches 114. The third passivation layer 130 may have a uniform thickness in some embodiments, or the third passivation layer 130 may be thicker at the bottom than on the sides. In some embodiments, the third passivation layer 130 may have the same composition as the passivation material 120, and in some embodiments, the third passivation layer 130 may be formed during the same deposition process as the passivation material 120. Also, the example of FIG. 9b includes cavities 132 in a center portion of the trenches (rather than the trenches being completely filled with insulating material).

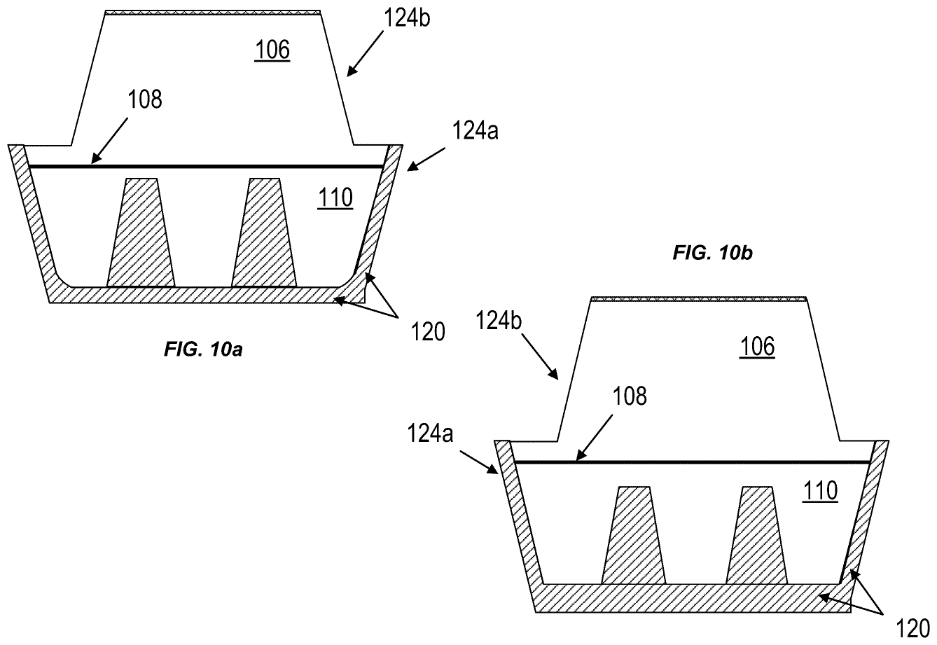

In FIG. 10a, corners (bottom corners in the figure) of the first mesa shape 124a are curved more than corners of the first mesa shape 124a in FIG. 10b. Also, in FIG. 10b, a thickness of the passivation material 120 is thicker along a bottom than along sidewalls of the first mesa shape 124a.

It should be appreciated that the features described in FIGS. 7a-7c, 8a-8c, 9a-9b, and 10a-10b may be present in mesa structures in accordance with some embodiments as single features (for example a single trench having one bottom corner that is curved more than the other) or as multiple features in any combination of the embodiments described herein.

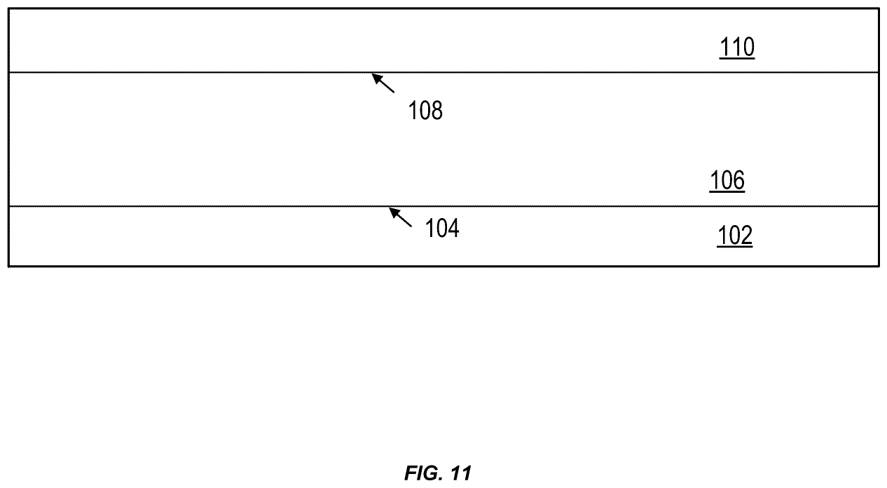

An exemplary process for forming the mesa structure including flipping the mesa onto the carrier substrate is described at FIGS. 11-25. FIG. 11 provides a structure that includes a SAC 104, MQW 108 and cladding 110 which are on a donor substrate 102. In an embodiment, the donor substrate 102 includes a SAC 104 overlay, with a MQW region 108 overlying the SAC 104, and a cladding region 110 on the MQW 108. The MQW region 108 may include a cladding 106 at the bottom-portion of the MQW 108 adjacent to the SAC 104. Some embodiments may include an n-buffer overlying the SAC 104, the cladding 106 may include an n-cladding, and/or the cladding 110 may include a p-cladding.

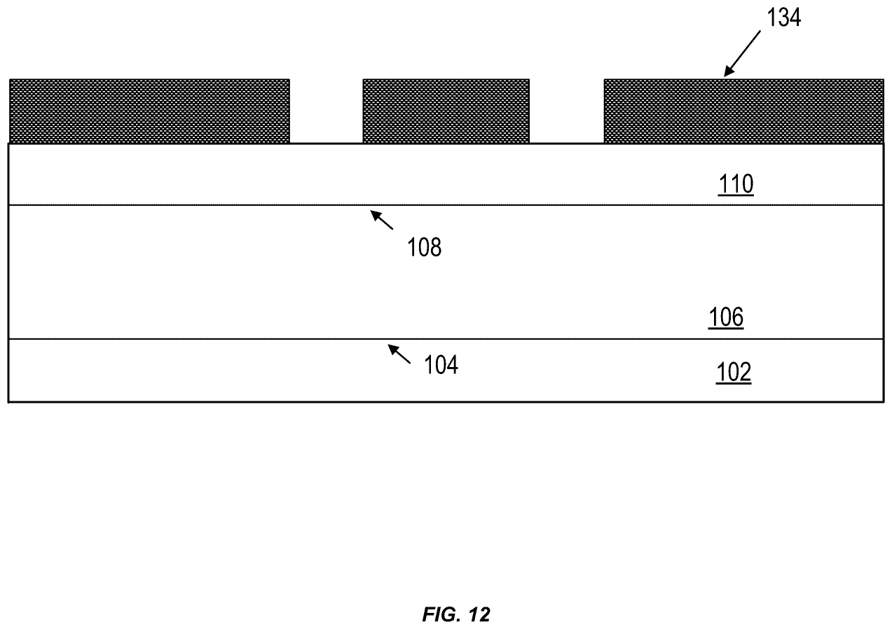

FIG. 12 provides an optional step to form ridge light cavity trenches. A patterned mask 134 is formed on the top surface of the cladding 110 with openings to define the lateral dimensions of the trenches. A masking material, such as photoresist, may enable the patterning to open the trench areas.

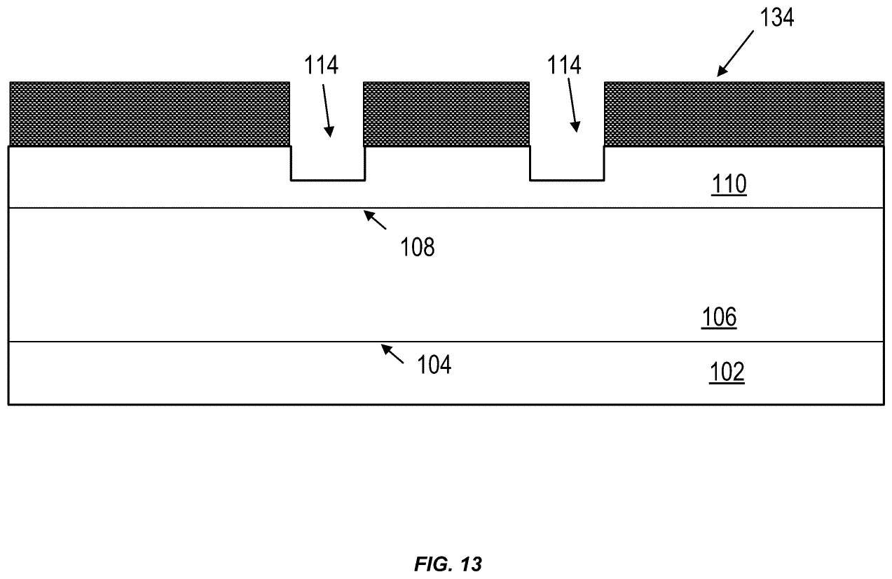

FIG. 13 shows the surface of the mesa structure after the trenches 114 are formed. The resultant light cavity ridge structure defined by the cavity trenches 114 may be referred to as “ridge-1”. The reason for ridge-1 is to define the laser diode ridge for certain designs for ridge laser diodes, for instance narrow-linewidth, single mode, or other ridge laser diode that would benefit from the cavity being defined by cavity trenches. The ridge-1 structure may be formed by a plasma etch to create the cavity trenches 114 and form the laser diode ridge. Note that the trench-defined ridge-1 structure may not be used in some embodiments (e.g., for multi-mode or higher-power lasers) and may not be needed for some low-power lasers.

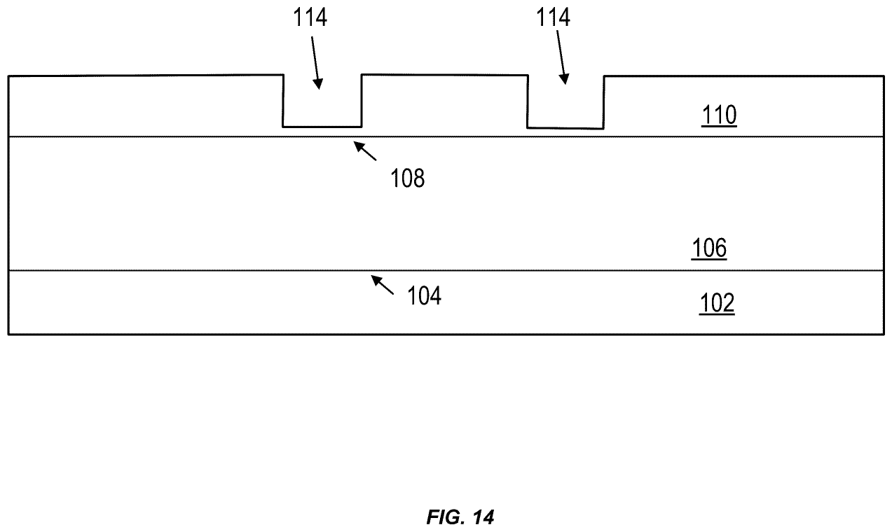

FIG. 14 shows the surface of the mesa structure after the mask is removed. As shown, the cavity trenches 114 are etched to stop within the cladding region 110. In other laser diode ridge designs, the cavity trenches 114 may be etched to stop just above the beginning of the MQW region 108 or a distance within or below the MQW region 108. Further note that the top surface (p-side) may be further processed to form electrically conductive structures (not shown) for electrical connections of the top side of the mesa (currently the top side—when flipped, this will become the bottom side) to connect to electrical contacts on a subsequent carrier substrate. Metallization for the electrically conductive structures may be formed before or after formation of the trenches 114 depending on the particular design and application.

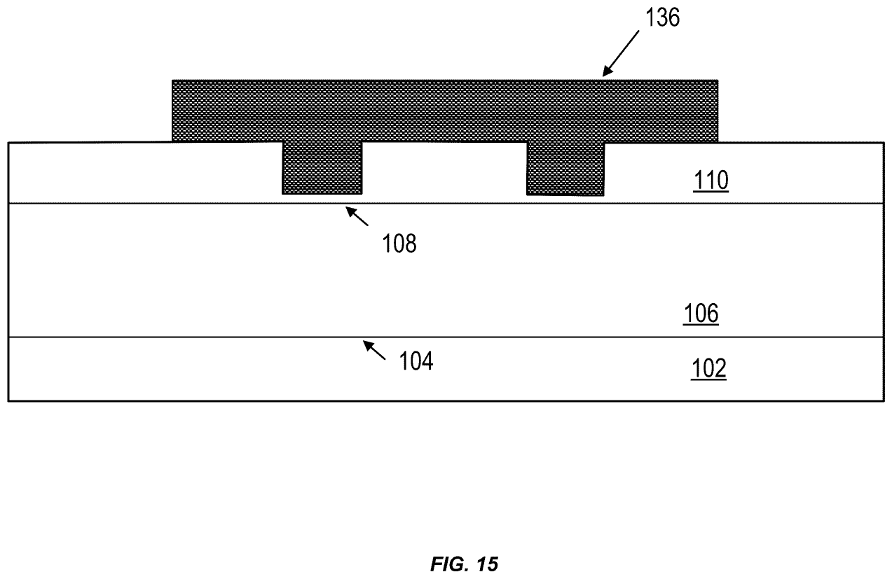

FIG. 15 shows a deposited and patterned masking material 136 on the mesa surface, so as to set up for a ridge etch. The reason for this ridge etch is to define the shelf, which may be referred to as “ridge-2” or, in the absence of ridge-1, the mesa etch may define the ridge itself, as a ridge-1 may not be needed for multi-mode or higher-power or wide cavity laser diodes. A shape of the sidewalls of the mesa structure may be appropriately modified by suitably changing the etching conditions.

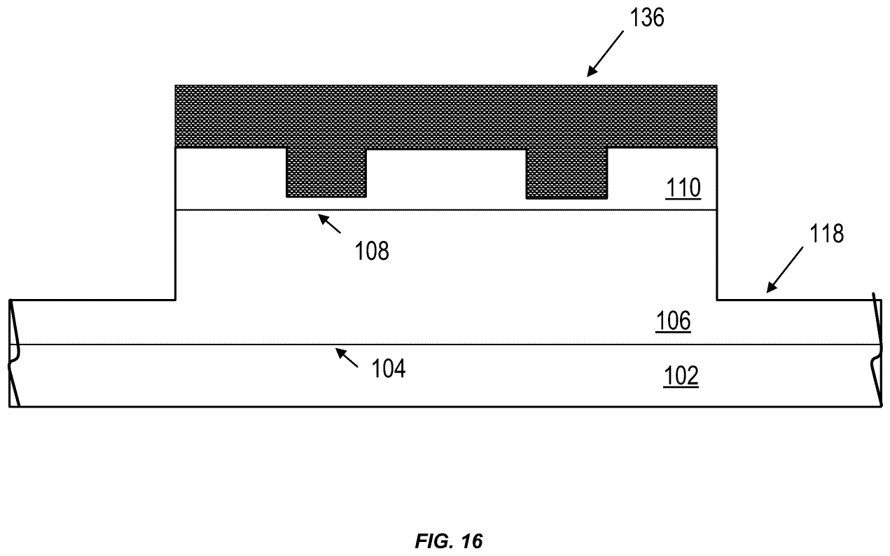

FIG. 16 illustrates ridge cutouts forming shelves 118 after the ridge-2 etch. The shelf-like structures jut out of the sidewalls of the mesa. The shelf etch is carried out down to a depth of the MQW 108 and stops above the SAC 104. The ridge-2 (or ridge in the case of a non-trench laser diode design) may be etched with a stopping point within or below the MQW region 108 before the depth reaches the SAC 104. The resultant etched structure may have the appearance of shelves 118 jutting out of each side.

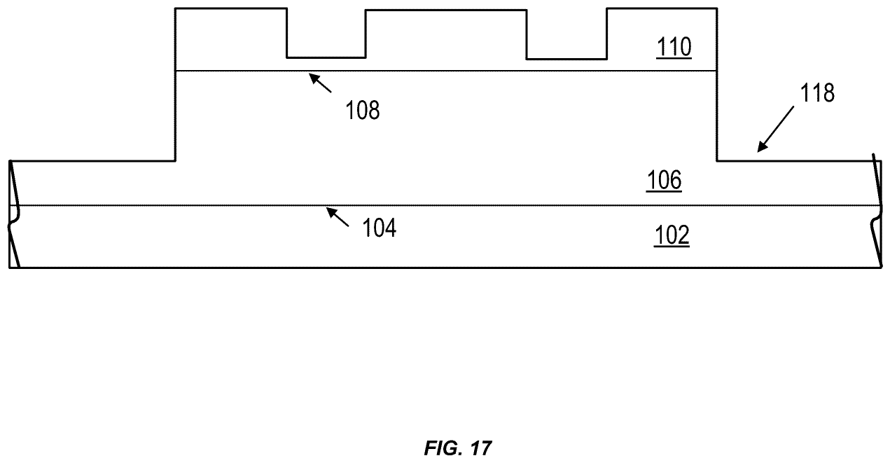

FIG. 17 illustrates the resulting mesa with the shelves 118 after the ridge-2 etch and after removal of the mask.

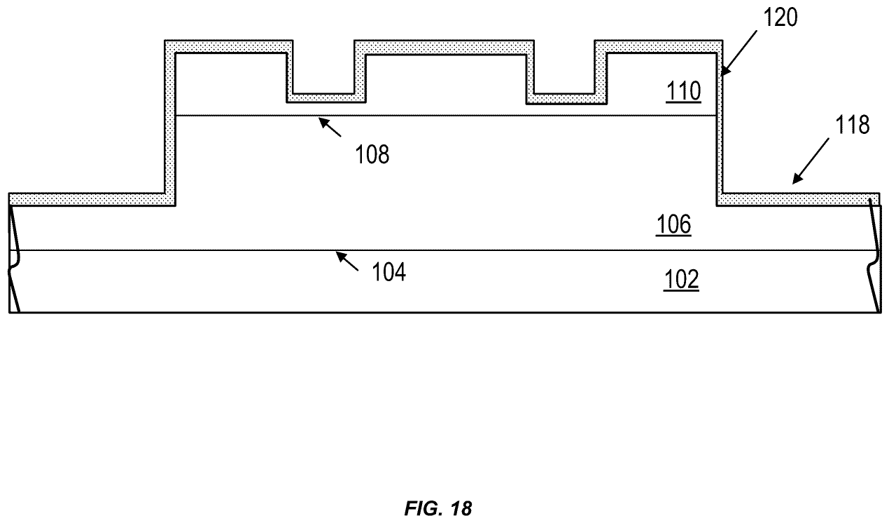

FIG. 18 shows the mesa of FIG. 17 after a blanket layer of passivation material 120 is deposited. The passivation material covers all surfaces including the horizontal portion of the shelves 118. The passivation material 120 may be selected to protect the mesa sidewalls from subsequent chemical etch processes effective to remove the SAC 104 while minimizing reactive effects with the materials in the MQW 108 and claddings 110, 106. The passivation material 120 may be a dielectric such as silicon dioxide, silicon nitride, silicon oxynitride, hafnium oxide, aluminum nitride, aluminum oxynitride, combinations thereof, or other dielectric materials or multiple different layers of dielectric materials. In an embodiment, the passivation layer 120 includes a first film of aluminum nitride or aluminum oxynitride and a second film of oxide formed on the first film. The passivation material 120 may be deposited to a thickness necessary to provide the protection sought against subsequent etch processes for the sidewalls, while sufficiently thin that, optionally, the passivation material 120 may remain for subsequent depositions. Note that although the drawing suggests that there is a further vertical cut portion on either side of the SAC 104, in actuality, the portion not covered by the passivation 120 may simply extend across the length of the substrate 102 and there may be multiple ridge structures produced using the described methods.

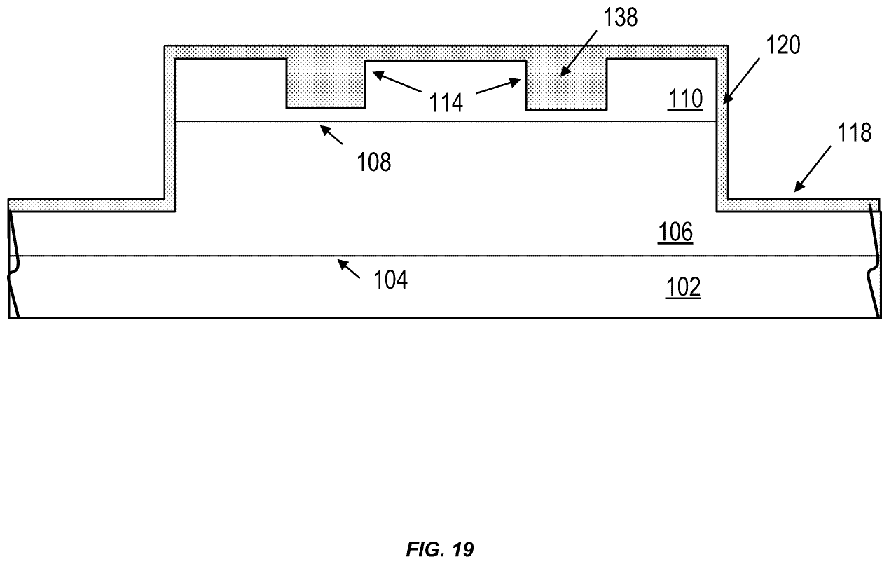

FIG. 19 shows the etched mesa structure with the passivation 120 and cavity trench fill 138. The cavity trench fill 138 may be of the same material as the passivation 120. This allows for the trench fill 138 to occur in the same or a different step as the blanket passivation 120 deposition. Alternatively, the trenches 114 may be at least partially filled with a different material including a metal-based, electrically conductive, heat conducting, and/or thermally conductive material. The trench fill 138 may facilitate subsequent physical or electrical connections. In some embodiments, the cavity trench 114 may be filled and a bonding layer (which may be the same electrically conductive or other thermally conductive material used to fill the cavity trenches) and may be formed on the top surface to a thickness sufficient to serve as a bonding layer to corresponding landings on the carrier substrate upon subsequent steps of flipping and transfer.

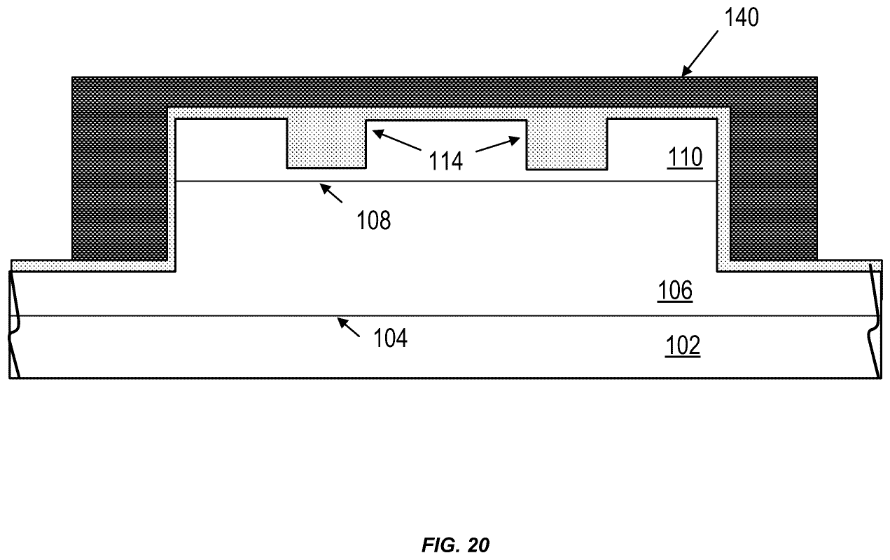

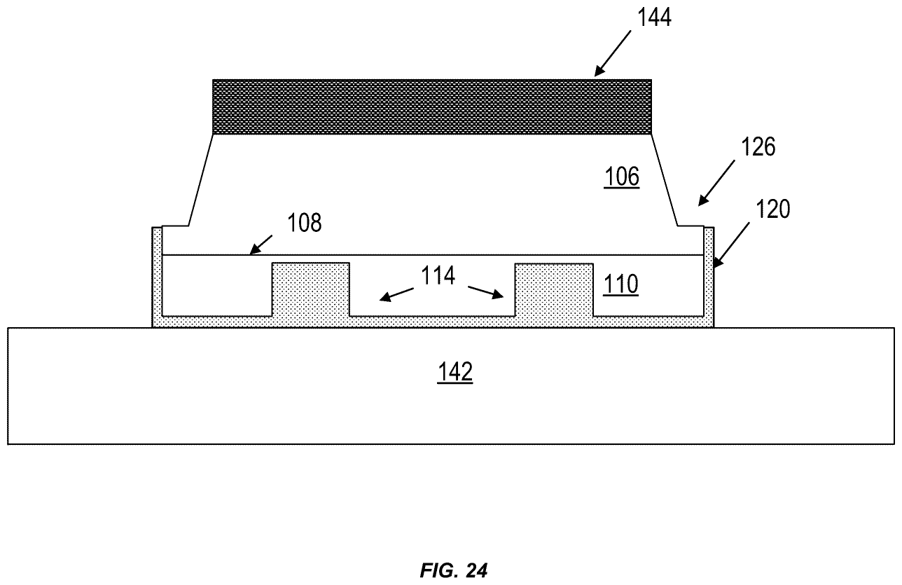

FIG. 20 shows the mesa of FIG. 19 after a mask 140 is deposited to define the lateral dimensions for a subsequent mesa etch. The mask 140 may be patterned so as to define the mesa (the structure representing the ridge(s) with the shelf). The masking step may be preparation for a subsequent step of removing the SAC 104 to enable the removal of the mesas to transfer them to a carrier substrate. The lateral dimensions of the subsequent mesa etch may be determined based on specifications for the physical dimensions of the laser diode as mounted on the substrate, to support a final mesa etch step (shown at FIG. 24).

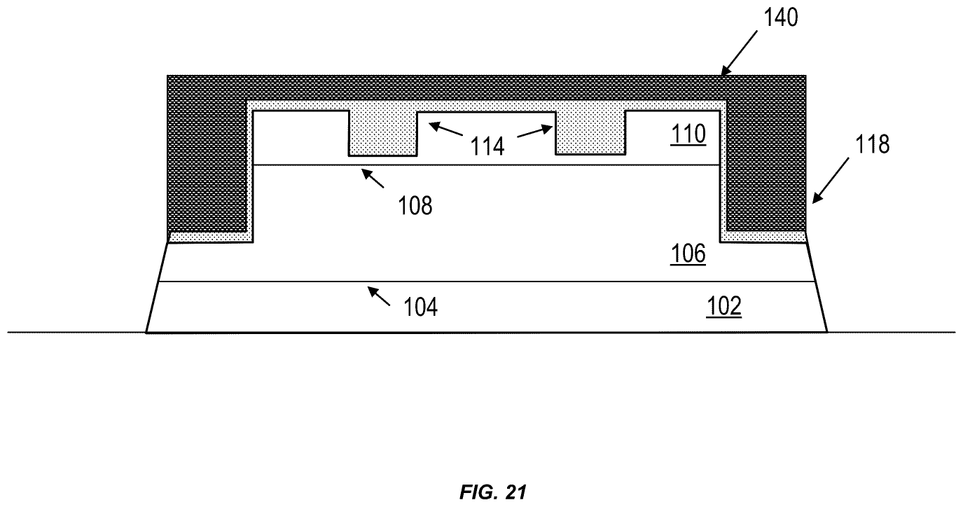

FIG. 21 shows the mesa of FIG. 20 after the etch is performed. Individual devices for transfer are defined using the mesa etch. The ridge cutouts and shelves 118 form a sub-mesa shape (the cladding 110, trenches 114, MQW 108, and upper portion of cladding 106) within the overall mesa. The mesa etch may cut through the remaining MQW 108 (and cladding 110, 106) as well as the SAC 104. The resultant etched mesa includes the (optional) ridge-1, the ridge-2 with shelves 118, and the cut mesa. With this step, the individual laser diodes are defined, the mask 140 can be removed, and the laser diodes can be removed from the donor substrate in a subsequent step.

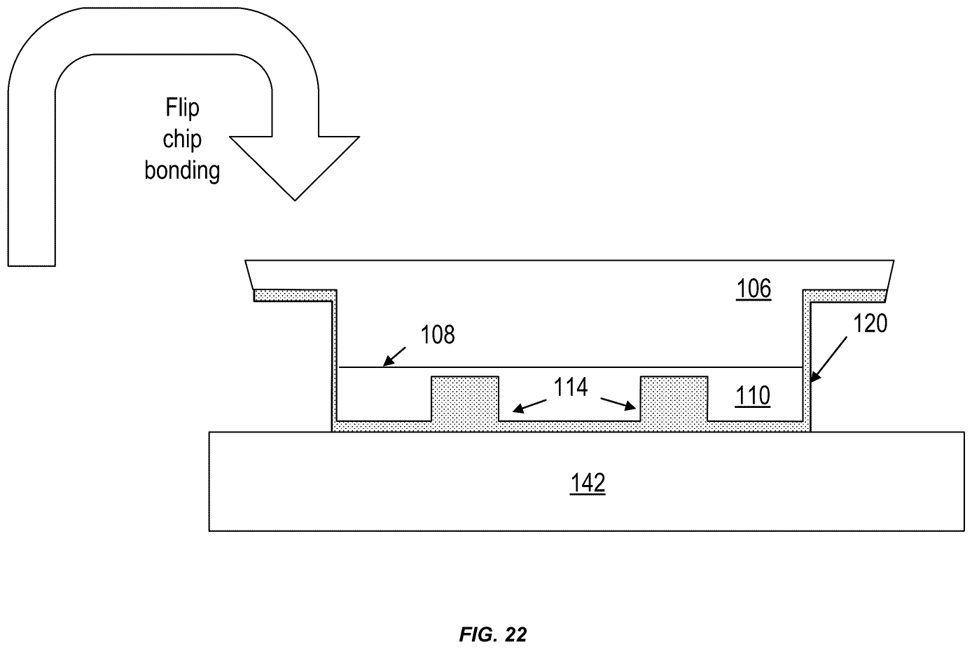

FIG. 22 shows the etched mesa after removal from the donor substrate and flipped upside down onto a carrier submount 142. The mesas may be removed from a GaN, GaAs, or another substrate and attached to the carrier 142. Bonding materials to facilitate mesa attach are not shown in this example. Note that to stick the mesa onto the carrier submount 142, the mesa must be bonded. One approach is to apply a bonding material, which may be an electrically conductive material such as a metal, onto the surface of the etched mesa prior to flipping and bonding onto pre-determined landing features on the carrier submount. Note that a portion of the passivation material 120 may need to be removed (not shown) to successfully deposit and enable the bonding. This passivation material removal can be done either before or after metallization. Or, if the passivation material is sufficiently thin and compatible with the bonding material, the passivation material may remain and the bonding material may be deposited on the passivation material depending on device structure (see FIGS. 26a-26f, 27a-27f, 28a-28b, 29a-29b, and 30a-30f for examples where a portion of the passivation material is removed and bonding regions are formed on p-contact regions). Removing the SAC 104 exposed after the mesa etch and/or the substrate 102 by etching enables the removal of the mesas to transfer them to the carrier substrate. Etching the SAC 104 may remove a portion of the substrate 102.

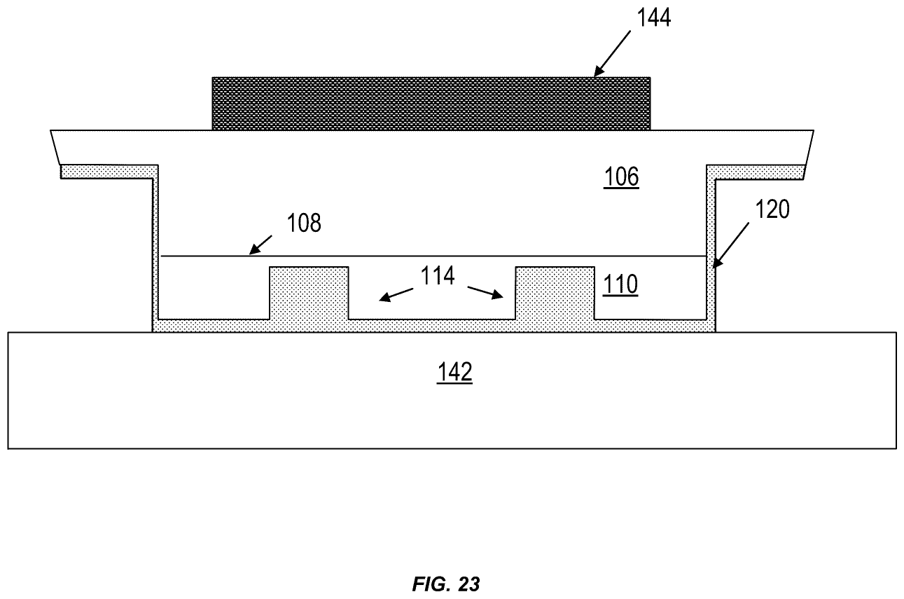

FIG. 23 shows the flipped mesa with an optional mask 144 formed thereon to further and finally cut the mesa to define the final lateral dimensions of the mesa on the carrier substrate 142. The final shape of the mesa may be pre-determined based on laser diode design considerations with respect to additional processing steps once placed on the carrier substrate 142. For example, if the mesa includes the laser cavity trenches 114, the final lateral mesa dimensions may be determined based on the layout requirements of the substrate. If the mesa does not include the laser cavity trenches, or ridge-2 would not define the laser cavity, then the final lateral mesa dimensions would define the laser cavity, in which case the laser device design may specify the final lateral mesa dimensions.

FIG. 24 shows how the cut mesa with cavity trenches 114 may appear post etch. A surface of the cladding 106 is exposed. The mesa sidewalls appear angled due to the angling effect of the etch process in some embodiments. The sidewalls may also be vertical, nearly vertical, or may be tapered. The desired shape may be based on laser diode design requirements. The etch is preferably stopped to form new post-transfer shelves 126. The shelves 126 may be fabricated to be just above the line represented by the active area in which the semiconductor junction activity for producing the light emission occurs, or may be within the active region (e.g., MQW 108), or may be formed to be below the active region depending on the laser design. As shown in FIG. 24, the passivation coating 120 could remain covering the etched mesa on the bottom portion of the sidewalls to protect the active region 108 depending on the shelf design.

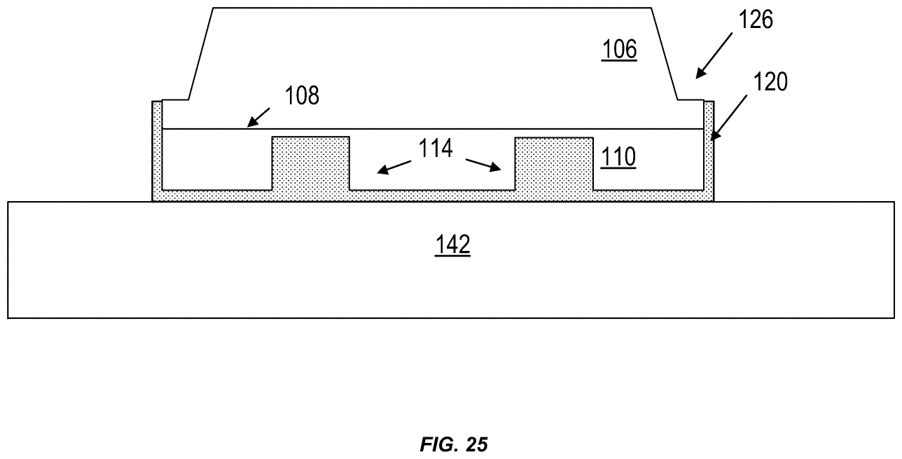

FIG. 25 shows the cut mesa after the mask material is removed. The cut mesa is ready for subsequent process steps carried out on the carrier substrate 142. These steps may include finishing the ridge laser diode facets (the facets may be formed while the mesa is on the donor substrate 142, for example by cleaving, or may be formed after transfer to the carrier substrate 142, for example by etching). Facet coatings may also be formed to facilitate a resonance effect to enable coherent light emission. These steps may also include further thinning of the cladding 106. In some embodiments, a final height of the structure may be defined by a thickness corresponding to at least a portion of the donor substrate that has been removed. The final height of the structure may be 20 μm or less. The final height of the structure may be 100 μm or less. The final height of the structure may be smaller than the height of the carrier substrate 142, and may be 10 μm or less. The final height of the structure includes the thicknesses of the claddings 106 and 110 and the MQW 108, and may further include the donor substrate 102. The final height of the structure can be realized by removing at least a portion of the donor substrate 102. Additional processing steps may include forming electrical contact point(s) on the surface of the flipped mesa and attaching wiring structures to couple the flipped mesa to power sources. To protect the mesa from surrounding devices, an isolation dielectric may be formed on either or both sides of the mesa. In some configurations, a portion of the passivation layer 120 (e.g., on a vertical side of the mesa) may be removed (e.g., etched).

The above process flow may be used for any ridge laser diode structure, including GaN-based ridge laser diodes, as well as GaAs, InP, InGaNP, or other types of ridge laser diodes which may be formed on GaN, GaAs, sapphire, silicon, or other donor substrates.

An example of a process flow and device structure in the context of red laser diodes begins in FIGS. 26a-26f. A substrate material, capable of forming the subsequent epitaxial layers for a red laser diode design, is selected for the donor substrate 102. A sacrificial region 104 may be formed thereon, the sacrificial region 104 being epitaxial thin film(s) suitable for growing the device stack on top, while capable of being selectively removed to separate the donor-side device prior to a flip and transfer step. The active region 108 (e.g., MQW or QW), which may be several epitaxial layers according to the desired laser diode characteristics, may be grown. Cladding 110, together with other top layers are then formed on the active region 108. The p-contact 146 is formed to enable electrical contact with a landing on the carrier substrate, as well as to define the dimensions of the active laser diode ridge (FIG. 26a). A mask 148 is deposited and patterned to create openings for a cavity trench etch (FIG. 26b). Note that cavity trench etch is optional depending on the laser diode design. If a cavity trench is not used, then the lateral dimensions of the p-contact define the lateral dimensions of the cavity portion. For purposes of the descriptions herein, it will be assumed that a cavity trench is used. As shown in FIG. 26c, after the cavity trenches 114 are formed, ridge shelves 150 are formed, and a blanket passivation layer 120 is deposited to cover the surface including the ridge shelves 150 (FIG. 26d). A mask 152 may be patterned on the surface to form openings 154 at the p-contact, so that contact vias may be etched (FIG. 26e). A bonding material 156 is placed over the top surface, and may be laterally trimmed so that the bonding area is suitable to attach to lands on the carrier substrate when flipped and transferred (FIG. 26f).

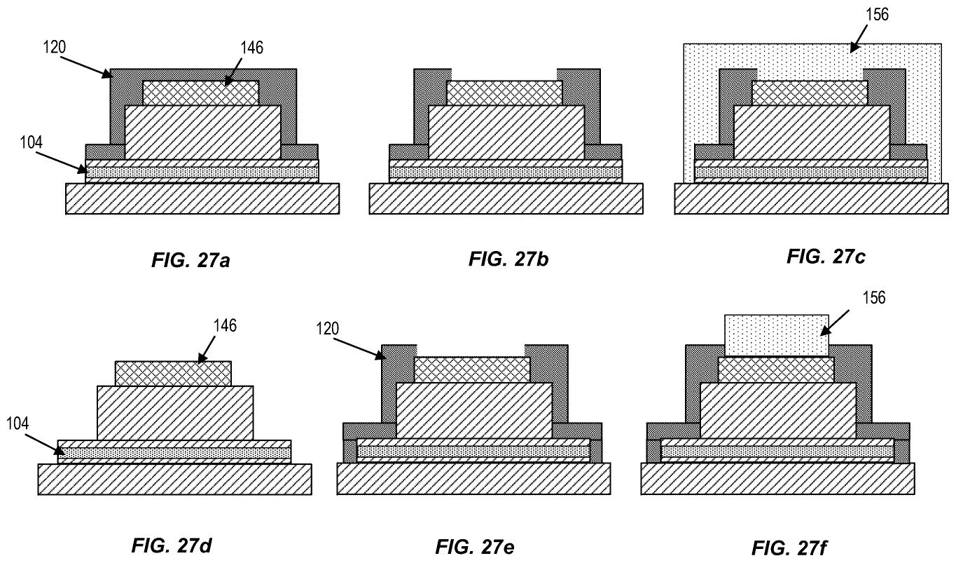

To facilitate the flip and transfer, some alternative schemes may be implemented for using anchors. For example, at FIGS. 27a-27f a simplified, non-cavity trench donor mesa structure is shown with a blanket passivation 120. As shown in FIG. 27a, the blanket passivation 120 is shown as stopped above the sacrificial layer 104 because the sacrificial layer 104 extends across the surface of the donor substrate prior to forming the mesas. The sacrificial layer 104 is opened to serve as a via for the p-contact 146. Though not shown, portions of the sacrificial layer 104 may opened by removing select areas of the passivation layer 120 near the edges of the mesas. Once the select areas of the passivation layer 120 are removed (FIG. 27b), a bonding material 156 may blanket deposited to extend down to those portions of the sacrificial layer 104 that are opened (FIG. 27c). The bonding material 156 can then serve as a temporary anchor. As shown in FIGS. 27d-27e, in some embodiments, the blanket deposited passivation layer 120 itself can be used as an anchor. Prior to depositing the passivation layer 120 (FIG. 27d), select areas of the sacrificial layer 104 may be covered with a mask to prevent deposition of the passivation layer 120 at the masked portions (FIG. 27e). In some embodiments, the blanket passivation layer 120 may be deposited first, and then covered with a mask with openings only at those portions of the sacrificial layer 104 to be opened, the unmasked portions of the blanket passivation layer 120 may be etched away and the mask removed. The result is a mesa with a passivation layer 120 that coats the sides including a portion of the sacrificial layer 104. The passivation layer 120 then can serve as a temporary anchor.

In some embodiments, similar to the trench-based cavity laser device, the mesa may be cut to the base, stopping above the sacrificial layer to create shelf-structures. A passivation layer may be deposited, a p-contact via etched, and a bonding material deposited thereon, wrapping around the entire structure and stopping at the base below the sacrificial layer. A portion of the bonding material may be selectively removed so that it remains only at the p-contact via, so that the bonding material may bond to the subsequent carrier substrate upon flipping.

Alternatively, the mesa may include shelf structures, and the p-contact formed on top of the mesa. A blanket passivation material may be deposited around the mesa structure down to the donor base below the sacrificial layer. The p-contact via may then be etched, and the bonding material may be selectively deposited on the p-contact via, or may be blanket deposited and then masked over the p-contact and etched to expose all surfaces other than the p-contact surface.

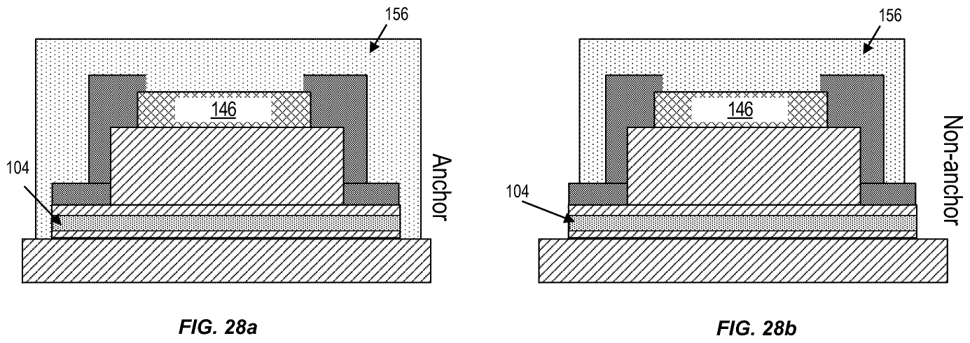

FIGS. 28a-28b show two different mesas, one that includes a bonding material anchor (FIG. 28a) and one that does not include an anchor (FIG. 28b). The mesas are set up for the flip and transfer. To carry out the flip and transfer, an anchor may be desired. If a blanket coated bonding material is used, then the bonding material 156 may serve as the anchor. In using the bonding material 156 as the anchor, the anchor structure may be formed in select portions of the device, so that other portions may leave the sacrificial layer 104 uncovered so that the sacrificial layer 104 may be etched away.

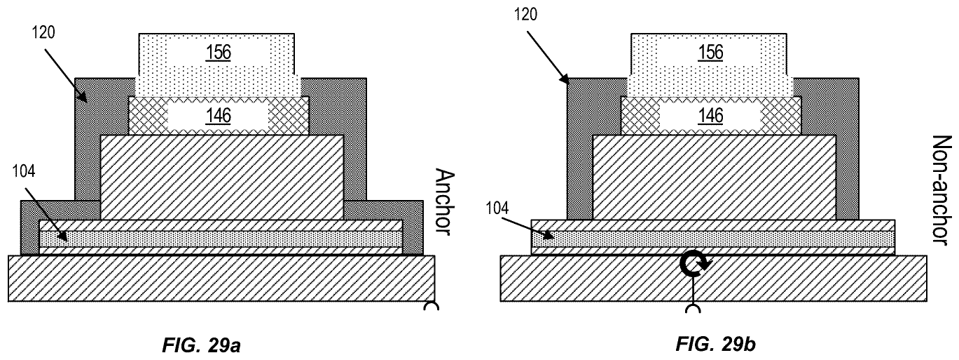

FIGS. 29a-29b two different mesas, one that includes a passivation layer anchor (FIG. 29a) and one that does not include an anchor (FIG. 29b). The mesas are set up for the flip and transfer. In an alternative scheme, as shown at FIGS. 27a-27f, the passivation material 120 that covers the sacrificial layer 104 in the lateral view can be used as an anchor. Other portions of the device may leave the sacrificial layer 104 uncovered.

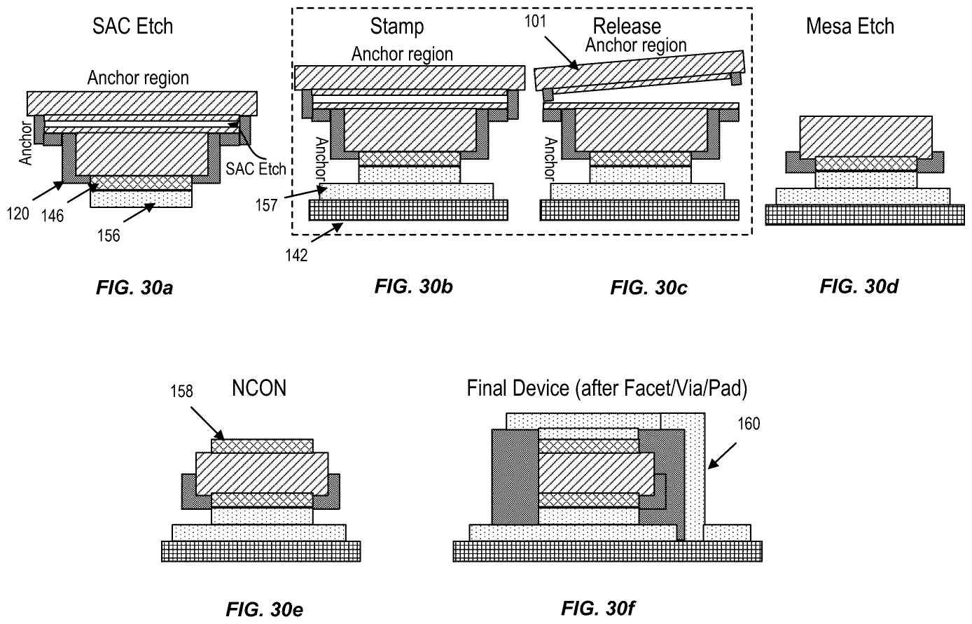

FIGS. 30a-30f are examples of how the anchor scheme as may be implemented herein and used in the flip and transfer process. For purposes of the example, there is provided a mesa device with the passivation layer anchor (FIG. 30a), for example as shown in FIGS. 29a-29b. The sacrificial layer may be removed, preferably using a wet chemical or other selective etch. The sacrificial layer may be removed in its entirety across the mesa portions (e.g., across all the mesa portions). The mesa is flipped upside down with the bonding material 156 on the bottom. The mesa is then attached to a landing 157 on a carrier substrate 142, which may be silicon carbide, aluminum nitride, silicon, or other suitable substrate that can accept the mesas for attachment and subsequent processing. The carrier substrate 142 may be made of a material having a higher thermal conductivity than that of gallium nitride. The carrier substrate 142 may be configured to have a lateral width larger than the lateral width of the mesa structure. The carrier substrate 142 may have previously fabricated landings 157 made of bonding material. The bonding material may be a metal. The flipped mesa may be pressed onto the landing 157 on the carrier substrate 142 with sufficient force to form a bonding material-to-bonding material interface to attach FIG. 30b), and then the donor substrate portion 101 is pulled away (FIG. 30c), leaving the mesa with the p-contact 146 coupled to the carrier substrate 142 (FIG. 30d). The top portion of the mesa, which is now the donor stack, may be trimmed back according to device design specifications. The mesa can then be finished with the formation of facets on the long ends of the mesa ridge, and n-contacts 158 and wirings to electrically connect the mesa to the carrier substrate 142 (FIG. 30e). A pad 160 may provide electrical connection to the carrier substrate 142 and/or may provide a heat dissipation plate (FIG. 30f).

In this example, the device with the passivation material as an anchor is shown flipped to bond to the carrier substrate. The anchor portions help the flipped device to remain gripped while being positioned on the landing areas 157 on the carrier substrate 142, and then the donor substrate 101 can be physically removed. The resulting mesa ridge has the p-contact 146 down and is ready for finishing. An n-contact 158 may be formed on top of the flipped mesa, and the device may then be further processed to form additional vias for electrical contacting with wiring on the carrier substrate 142.

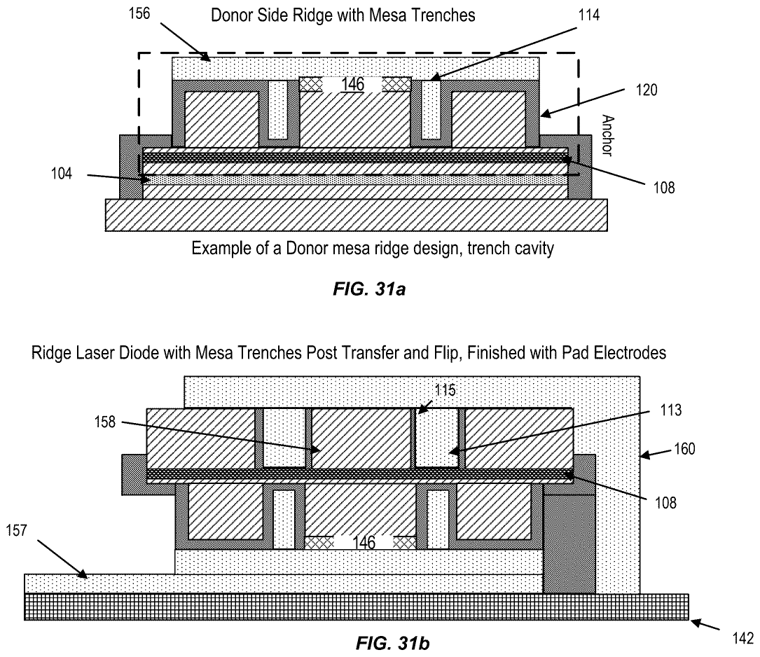

FIGS. 31a-31b are an example of a trench-cavity ridge formed on the donor 102, with the donor stack, cavity trenches 114, a p-contact 146, ridge shelf structure, passivation layer 120, and bonding layer 156, before flip and transfer while on the donor substrate 102, and after flip and transfer onto the carrier substrate 142, wherein the p-contact 146 may be interfaced with corresponding landings 157 on the carrier substrate 142 using the bonding material 156 (FIG. 31a). Once transferred and flipped, the device may be finished after remaining process steps including n-contact 158, facet, and pad formation. For instance, additional n-side trenches 113 may be formed on either side of the trench-defined cavity (FIG. 31b). In the example shown, the n-side trenches 113 stop above the active region 108 which extends along the lateral dimension of the mesa. The n-side trenches 113 may include a passivation layer 115. The n-side mesa surface may be covered with conductive material 160 to form electrical contacts to power and ground, as well as to serve as thermal dissipation paths.

In some embodiments, after flip and transfer of the trench cavity mesa ridge, the device may be finished according to design requirements. This example shows a trench-cavity ridge flipped laser diode with shallow trenches 113 formed on the n-side post flip. The shallow trenches 113 may be passivated to protect the donor stack. The passivation may be a thickness sufficient to protect the donor stack material from interactions with subsequent processing or materials but thin enough to allow for thermal conductivity. The remainder of the shallow trenches 113 may be filled with thermally conductive material such as gold or copper, which may be the same as the bond pad material for the n-side or may be a different material.

In the example shown, the n-side shallow trenches 113 may be etched to the same lateral location as the cavity trenches 114 directly below on the other side of the MQW 108 (shown as QWs in the drawing) and may be nearly the same width as the cavity trenches 114. The widths of trench 113 and trench 114 may be the same or different. For example, the width of trench 113 may be larger than or smaller than the width of trench 114. Trench 113 may at least partially overlap trench 114 in the stacking direction, or may not overlap trench 114. FIGS. 313a-31b illustrates a case in which trench 113 overlaps trench 114 in the stacking direction. The numbers of trenches 113 and trenches 114 may be different or may be the same.

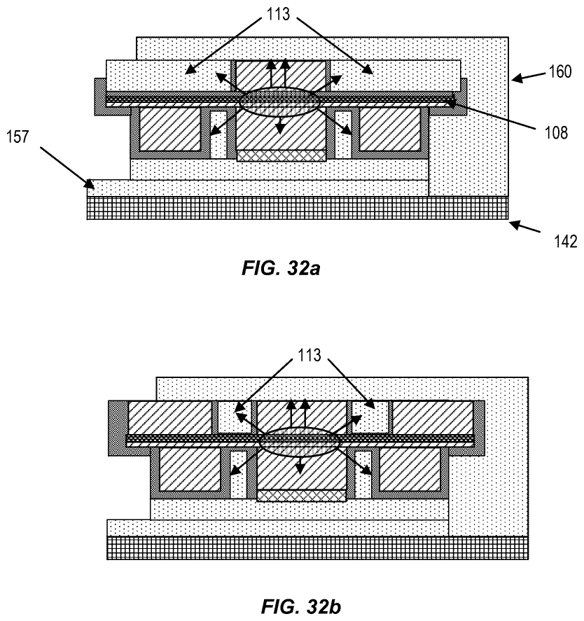

FIGS. 32a-32b are an example of a laser device design with alternative schemes for the n-side shallow trenches 113. The n-side shallow trenches 113 may extend to a depth above the active region 108, but the lateral dimension of the shallow trenches 113 may be consistent with the cavity trenches, or may be wider extending to near or at the edge of the mesa shelf (FIG. 32a). Other details shown in the drawings relate to options for conductive material structures depending on the electrical design of the device. The cavity portion is shown at the center between the cavity trenches. The arrows drawn emanating from the cavity portion is a concept view of the heat dissipation from the cavity portion.

Post flip and transfer, the laser diode design may include shallow trenches 113 as shown on the bottom in FIGS. 32a-32b. On the top is shown an alternative design where the shallow trenches 13 extend across the width of the mesa so that the n-side of the mesa is trenched and filled with thermally conductive material except for the area that contains the cavity. The arrows emanating from the cavities show the conceptual thermal pathways to remove heat from the cavity and out through the thermally conductive materials for dissipation out of the laser diode device (FIG. 32b).

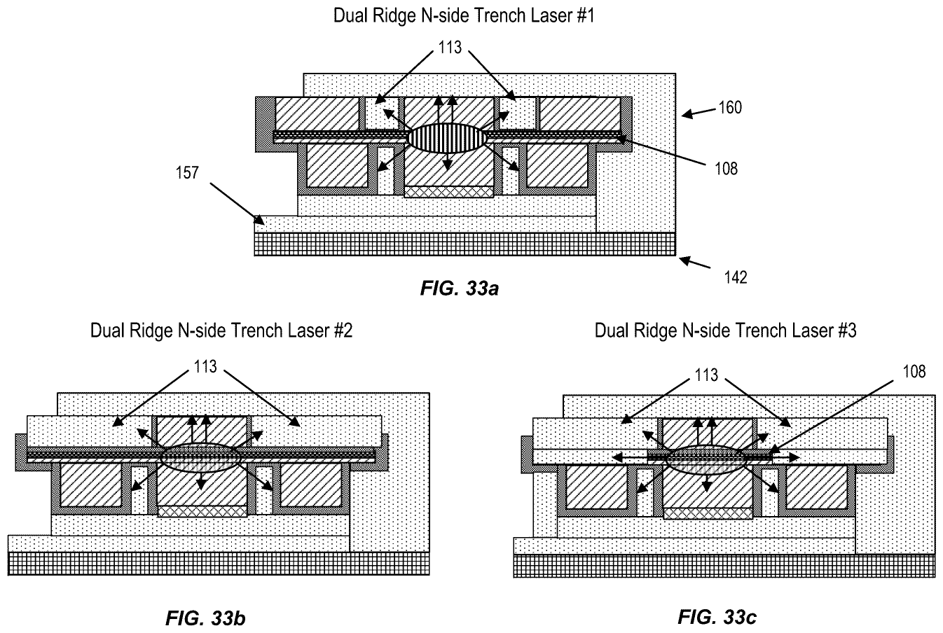

FIGS. 33a-33c present three examples where, for thermal conduction reasons, the conductive material may be thicker. Examples 1, 2 and 3 show design variants where a thicker donor stack may be used to generate the desired photonic emission. As shown in FIG. 33a, in example 1, the n-side shallow trenches 113 may be aligned with and have similar lateral dimension as the cavity-trenches on the p-side. The n-side trenches 113 extend to a point above the active region 108 and may be passivated and filled with conductive material, and the conductive material may be deposited to a desired thickness above the mesa based on design tolerances for electrical contacts and thermal conduction (FIG. 33b).

Example 2 shows a similar n-side shallow trench scheme except that the lateral dimension of the shallow trenches 113 extends wide, to near the edge of, at the edge of, or extending beyond the edge of the mesa shelf (FIG. 33c). The n-side shallow trenches 113 are filled with conductive material and the conductive material may be deposited to a desired thickness above the mesa based on design tolerances for electrical contacts and thermal conduction.

Example 3 shows a variation on the formation of the n-side shallow trenches 113. Instead of the shallow trenches 113 extending to a point above the active region 108, the shallow trenches are formed to a point beyond the active region 108. In this scheme, the sidewalls of the mesa at the cavity portion may be protected. This can be achieved using an etch to form mesa cavity sidewall shelves, and passivating to protect the sidewall including the shelf edges and the top surface of the mesa extending away from the mesa cavity portion. The space created by the etching to form the mesa cavity sidewall shelves can be filled with conductive material and the conductive material may be deposited to a desired thickness above the mesa based on design tolerances for electrical contacts and thermal conduction.

In Example 3, prior to forming the n-side shallow-trenches 113, the n-side mesa may be trimmed back to laser device design tolerances, so as to further increase the space available for thermal transfer out of the cavity. Whereas in Examples 1 and 2, the n-side shallow trench depth does not dip below the active region 108 (shown as a horizontal line), in Example 3 the n-side shallow trench 113 extends below the line of the active region 108 and stops on the donor stack beyond the active region 108. A benefit of extending the n-side shallow trench 113 farther down and beyond the active region 108 is to enable further enlarging of the shallow-trench fill, and/or to shrink the thickness of the donor stack mesa on either side of the cavity portion of the laser diode device. With less thickness of the mesa, there is less area for heat emanating from the cavity to absorb. This provides a greater volume through which the heat from the cavity can travel to dissipate out of the laser diode. To enable a deeper n-side shallow trench 113, the sidewalls of the mesa at the cavity portion may be protected. This can be achieved using a sidewall passivation protection shelf-structure with the passivation extending down the lateral and horizontal sides of the mesa on the top side.

It should be noted that the laser diode device structures described may include features and fabrication process steps that help to solve laser diode device design problems seen for a variety of colors. The descriptions are therefore not limited to the contexts provided. For instance, the flipped device having the n-side trenches may be useful for red due to the thermal dissipation challenges associated with gallium and arsenic crystalline structures, but the laser devices with a different wavelength and color may use a similar or variation of the n-side trench structure. Other embodiments and configurations may be used by those skilled in the art.

The specific details of particular embodiments may be combined in any suitable manner without departing from the spirit and scope of embodiments of the invention. However, other embodiments of the invention may be directed to specific embodiments relating to each individual aspect, or specific combinations of these individual aspects.

The above description of exemplary embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated.

A recitation of “a”, “an”, or “the” is intended to mean “one or more” unless specifically indicated to the contrary.

All patents, patent applications, publications, and descriptions mentioned here are incorporated by reference in their entirety for all purposes. None is admitted to be prior art.

What is claimed is:

1. A method of forming a mesa structure providing active region protection, the mesa structure including a plurality of epitaxially-grown semiconductor layers configured to enable generation of photonic emissions within a cavity, the mesa structure characterized by a length with two ends, comprising:
forming an epitaxially-grown sacrificial layer overlying a top surface of a donor substrate;
forming an epitaxially-grown first cladding region overlying the sacrificial layer;
forming an epitaxially-grown quantum well region overlying the first cladding region;
forming an epitaxially-grown second cladding region overlying the quantum well region, the second cladding region having a substantially flat top surface;
etching the sacrificial layer, the first cladding region, the quantum well region, and the second cladding region to form sidewalls extending from the top surface of the second cladding region to the donor substrate to form an overall mesa shape when viewed in cross section perpendicular to the length, the sidewalls including ridge cutouts so as to form a sub-mesa within the mesa shape, the ridge cutouts extending from the top surface of the second cladding region a distance down each sidewall toward the donor substrate and terminating within the first cladding region to form shelves;
forming a first passivation material over the top surface of the second cladding region and the sidewalls and the shelves of the ridge cutouts;
forming a via extending through the first passivation material to the top surface of the second cladding region;
forming a contact region in the via, the contact region formed on or within an upper portion of the second cladding region; and
forming an anchor material on a surface of the mesa structure, wherein along the length of the mesa structure, the anchor material extends down the sidewalls of the mesa structure and terminates at the top surface of the donor substrate to form anchor portions, and wherein along the ends of the mesa structure, the anchor material extends down the sidewalls of the mesa structure and terminates above the top surface of the donor substrate to form non-anchor portions.

2. The method of claim 1 wherein the first passivation layer covers the quantum well region along the sidewalls of the ridge cutouts, the method further comprising etching at least one of the sacrificial layer or the donor substrate exposed along the ends of the mesa structure.

3. The method of claim 1 further comprising:
forming a bonding material on the top surface of the second cladding region;
bonding the mesa structure to a carrier substrate;
removing the sacrificial layer so that the mesa structure is coupled to the donor substrate by the anchor portions; and
removing the donor substrate from the mesa structure by detaching the anchor portions.

4. A mesa structure providing active region protection, the mesa structure including a plurality of semiconductor layers, the mesa structure characterized by a length with two ends, comprising:
a donor substrate having a top surface;
a sacrificial layer overlying the top surface of the donor substrate;
a first semiconductor region overlying the sacrificial layer;
an active region overlying the first semiconductor region;
a second semiconductor region overlying the active region, the second semiconductor region having a substantially flat top surface;
sidewalls extending from the top surface of the second semiconductor region to the donor substrate to provide an overall mesa shape when viewed in cross section perpendicular to the length, the sidewalls including ridge cutouts so as to form a sub-mesa within the mesa shape, the ridge cutouts extending from the top surface of the second semiconductor region a distance down each sidewall toward the donor substrate and terminating within the first semiconductor region to form shelves;
a first passivation material coating the top surface of the second semiconductor region and the sidewalls and the shelves of the ridge cutouts;
a contact region on or within an upper portion of the second semiconductor region;
a via extending through the first passivation material to the contact region; and
an anchor material coating a surface of the mesa structure, wherein along the length of the mesa structure, the anchor material extends down the sidewalls of the mesa structure and terminates at the top surface of the donor substrate to form anchor portions, and wherein along the ends of the mesa structure, the anchor material extends down the sidewalls of the mesa structure and terminates above the top surface of the donor substrate to form non-anchor portions.

5. The mesa structure of claim 4 further comprising a pair of trenches each extending from the top surface of the second semiconductor region toward the active region, the pair of trenches separated from each other by a lateral distance.

6. The mesa structure of claim 5 wherein the pair of trenches extend into the second semiconductor region and terminate before reaching the active region.

7. The mesa structure of claim 5 wherein the pair of trenches extend into the second semiconductor region and terminate within the active region.

8. The mesa structure of claim 5 wherein the pair of trenches extend through the second semiconductor region and the active region.

9. The mesa structure of claim 5 wherein a bottom corner of at least one of the pair of trenches has a curved shape.

10. The mesa structure of claim 5 wherein at least one of the pair of trenches has, in cross section, two corners on a bottom side, and one of the corners has a greater curvature than the other corner.

11. The mesa structure of claim 5 wherein the first passivation material lines sides of at least one of the pair of trenches.

12. The mesa structure of claim 5 wherein the first passivation material lines sides and a bottom of at least one of the pair of trenches, and a thickness of the first passivation material along the bottom is greater than a thickness of the first passivation material along the sides.

13. The mesa structure of claim 5 wherein the first passivation material lines sides and a bottom of at least one of the pair of trenches to form a cavity in a center portion of the trench.

14. The mesa structure of claim 5 wherein the first passivation material fills at least one of the pair of trenches.

15. The mesa structure of claim 4 wherein a thickness between the top surface of the donor substrate and the top surface of the second semiconductor region is 20 μm or less.

16. The mesa structure of claim 4 wherein a thickness of the first passivation layer is greater on the top surface of the second semiconductor region than on the sidewalls of the ridge cutouts.

17. The mesa structure of claim 4 wherein the first passivation material comprises a first film of aluminum nitride or aluminum oxynitride and a second film of oxide overlying the first film.

18. The mesa structure of claim 4 wherein the first semiconductor region includes a first cladding region, the active region includes a quantum well region, and the second semiconductor region includes a second cladding region.

19. A mesa structure on a carrier substrate, the mesa structure including a plurality of semiconductor layers, comprising:
a bonding material coupling the mesa structure to the carrier substrate, wherein the bonding material is coupled to a contact region of the mesa structure;
a first semiconductor region comprising the contact region;
an active region overlying the first semiconductor region; and
a second semiconductor region overlying the active region, the second semiconductor region and the first semiconductor region having substantially flat surfaces that are substantially parallel to each other and form opposing upper and lower boundaries of the mesa structure respectively, the substantially flat surface of the first semiconductor region coupled to the carrier substrate by the bonding material;
wherein the first semiconductor region, the active region, and a portion of the second semiconductor region form a first mesa shape, and the remaining portion of the second semiconductor region forms a second mesa shape,
wherein sidewalls of the first mesa shape extend upward and outward from the substantially flat surface of the first semiconductor region in a direction toward the second mesa shape, and a passivation material extends along the sidewalls of the first mesa shape, and
wherein sidewalls of the second mesa shape extend downward and outward from the substantially flat surface of the second semiconductor region in a direction toward the first mesa shape.

20. The mesa structure of claim 19 wherein the first semiconductor region includes a p-type cladding region, the active region includes a quantum well region, and the second semiconductor region includes an n-type cladding region.
